(19) United States
(12) Patent Application Publication
(10) Pub. No.: US 2025/0241175 A1
(43) Pub. Date: Jul. 24, 2025

(54) Display Device

(71) Applicant: LG Display Co., Ltd., Seoul (KR)

(72) Inventors: SangUk Ahn, Paju-si (KR); HeeYoung Kwack, Paju-si (KR); TaeHo Kim, Paju-si (KR)

(21) Appl. No.: 18/936,834

(22) Filed: Nov. 4, 2024

(30) Foreign Application Priority Data
Jan. 23, 2024 (KR) 10-2024-0010110

(51) Int. Cl. H10K 59/80; H10K 59/131

(52) U.S. Cl. CPC H10K 59/873; H10K 59/131; H10K 59/80521

(57) ABSTRACT

A display device capable of preventing or reducing corrosion and side permeation is configured to disconnect the light emitting stack and the cathode by including a substrate including a through-hole, a display area surrounding the through-hole, and a surrounding area between the through-hole and the display area, a light emitting element disposed in the display area, an insulation film disposed on the substrate, and a disconnection leading structure positioned in the surrounding area and including a void portion in a lower portion thereof.

### CROSS-REFERENCE TO RELATED APPLICATION

This application claims priority to Republic of Korea Patent Application No. 10-2024-0010110, filed on Jan. 23, 2024, which is hereby incorporated by reference in its entirety.

### BACKGROUND

### Technical Field

Embodiments of the disclosure relate to a display device, and more specifically, for example, without limitation, to a display device capable of low power consumption by enhancing the lifespan by preventing or reducing side permeation and corrosion.

### Description of Related Art

As technology advances, the uses of display devices are becoming more diverse. Further, as display devices become thinner and lighter, their range of use is expanding.

As the area occupied by the display area for displaying images in the display device increases, various functions associated with or linked to the display device are added.

As design for allowing the display area to look full, so-called bezel-less or bezel-free design, becomes commonplace, research efforts are required for display devices having an area for adding various features as well as image display, inside the display area.

Accordingly, proposed are hole-in displays (HIDs) or hole-in active area (HiAA) displays in which at least a portion of the substrate has been removed in the display area of the display panel.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

The display quality may deteriorate due to penetration of, e.g., moisture through a side surface from the substrate-removed area in the display area or a conductive path. Accordingly, the inventors of the disclosure have invented a display device for preventing or reducing a conductive path through a cathode and side permeation by a light emitting stack.

Exemplary embodiments of the disclosure may provide a display device capable of blocking a side permeation path by a light emitting stack by including a disconnection leading structure including a void portion.

Exemplary embodiments of the disclosure may provide a display device capable of blocking a conductive path caused by a cathode by having a disconnection inducing structure including a void portion.

Exemplary embodiments of the disclosure may provide a display device capable of preventing or reducing side permeation and corrosion by disconnecting a cathode and a light emitting stack by including a disconnection leading structure including a void portion.

Exemplary embodiments of the disclosure may provide a display device capable of low power consumption by enhancing the lifespan by preventing or reducing side permeation and corrosion.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

Exemplary embodiments of the disclosure may provide a display device comprising a substrate including a through-hole, a display area surrounding the through-hole, and a surrounding area between the through-hole and the display area, a light emitting element disposed in the display area, an insulation film disposed on the substrate, and a disconnection leading structure positioned in the surrounding area and including a void portion in a lower portion thereof.

The disconnection leading structure may include a first metal layer disposed on the insulation film, the void portion disposed on the first metal layer, a third metal layer disposed on the void portion, and an organic film covering the first metal layer, the void portion, and the third metal layer.

Exemplary embodiments of the disclosure may provide a display device comprising a substrate including a through-hole, a display area surrounding the through-hole, and a surrounding area between the through-hole and the display area, a light emitting element disposed in the display area, an insulation film disposed on the substrate, an organic film positioned in the surrounding area and including an undercut area recessed inward in a lower portion thereof, a first metal layer positioned in the undercut area and disposed on the insulation film, a third metal layer overlapping the first metal layer and disposed on an upper surface of the undercut area, and a void portion disposed between the first metal layer and the third metal layer.

Exemplary embodiments of the disclosure may provide a display device comprising a substrate including a through-hole, a display area surrounding the through-hole, and a surrounding area between the through-hole and the display area, a light emitting element disposed in the display area, an insulation film disposed on the substrate; an organic film positioned in the surrounding area and including an undercut area recessed inward in a lower portion thereof, and a void portion disposed on the upper surface of the undercut area.

According to exemplary embodiments of the disclosure, there may be provided a display device capable of blocking a side permeation path by a light emitting stack by including a disconnection leading structure including a void portion.

According to exemplary embodiments of the disclosure, there may be provided a display device capable of blocking a conductive path caused by a cathode by having a disconnection inducing structure including a void portion.

According to exemplary embodiments of the disclosure, there may be provided a display device capable of preventing or reducing side permeation and corrosion by disconnecting a cathode and a light emitting stack by including a disconnection leading structure including a void portion.

According to exemplary embodiments of the disclosure, there may be provided a display device capable of low power consumption by enhancing the lifespan by preventing or reducing side permeation and corrosion.

It is to be understood that both the foregoing general description and the following detailed description of the present disclosure are exemplary and explanatory and are intended to provide further explanation of the disclosure as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features, and advantages of the disclosure will be more clearly understood from the following detailed description, taken in conjunction with the accompanying drawings, in which:

FIG. 1 is a view illustrating a system configuration of a display device according to exemplary embodiments of the disclosure.

FIG. 2 illustrates an equivalent circuit diagram illustrating a subpixel in a display panel according to exemplary embodiments of the disclosure.

FIG. 3 is a plan view illustrating a structure of an optical area of a display panel according to exemplary embodiments of the disclosure.

FIG. 4 is a cross-sectional view taken along line I-I′ of FIG. 3 according to exemplary embodiments of the disclosure.

FIG. 5 is a cross-sectional view taken along line II-II' of FIG. 3 according to exemplary embodiments of the disclosure.

FIG. 6 is an example cross-sectional enlarged view illustrating area X of FIG. 5 according to exemplary embodiments of the disclosure.

FIG. 7 is a view illustrating a moisture permeation path and a conductive path in a disconnection leading structure as illustrated in FIG. 6 according to exemplary embodiments of the disclosure;

FIG. 8 is another example cross-sectional enlarged view illustrating area X of FIG. 5 according to exemplary embodiments of the disclosure.

FIG. 9 is another example cross-sectional enlarged view illustrating area X of FIG. 5 according to exemplary embodiments of the disclosure.

FIG. 10 is another example cross-sectional enlarged view illustrating area X of FIG. 5 according to exemplary embodiments of the disclosure.

FIG. 11 is another cross-sectional view taken along line II-II′ of FIG. 3 according to exemplary embodiments of the disclosure.

FIG. 12 is another cross-sectional view taken along line II-II′ of FIG. 3 according to exemplary embodiments of the disclosure.

FIG. 13 is another cross-sectional view taken along line II-II′ of FIG. 3 according to exemplary embodiments of the disclosure.

FIGS. 14, 15, 16, 17, and 18 are views illustrating a process of forming a disconnection leading structure of a display panel according to exemplary embodiments of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The progression of processing steps and/or operations described is an example; however, the sequence of steps and/or operations is not limited to that set forth herein and may be changed as is known in the art, with the exception of steps and/or operations necessarily occurring in a particular order. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

The features of the various embodiments of the present disclosure may be partially or entirely combined with each other, and may be technically associated with each other or operate with each other. The embodiments may be implemented independently of each other and may be implemented together in an association relationship.

Hereinafter, various embodiments of the disclosure are described in detail with reference to the accompanying drawings. The scales of the components shown in the drawings have different scales from the actual ones for convenience of explanation, and thus are not limited to the scales shown in the drawings.

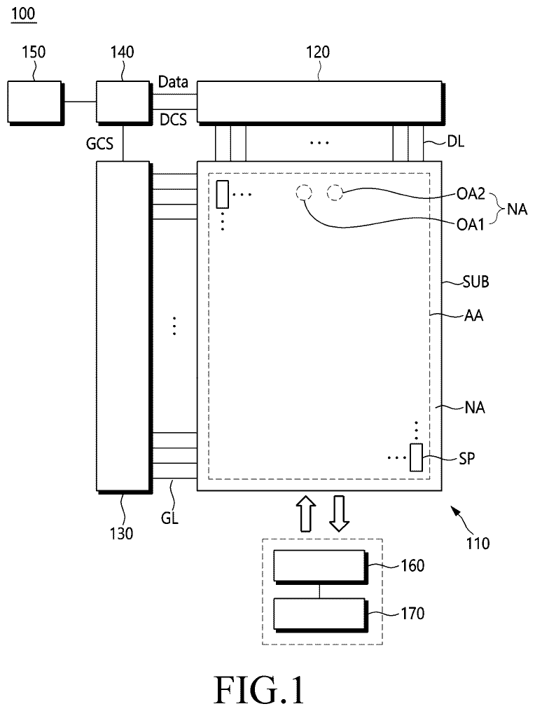

FIG. 1 is a view illustrating a system configuration of a display device 100 according to exemplary embodiments of the disclosure.

Referring to FIG. 1, a display device 100 may include a display panel 110 and display driving circuits, as components for displaying images.

The display driving circuits are circuits for driving the display panel 110 and may include a data driving circuit 120, a gate driving circuit 130, and a display controller 140.

The display panel 110 may include a display area AA in which images are displayed and a non-display area NA in which no image is displayed. The non-display area NA may be an outer area of the display area AA and be referred to as a bezel area or an edge area. The whole or part of the non-display area NA may be an area visible from the front surface of the display device 100 or an area that is bent and not visible from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to exemplary embodiments of the disclosure may be a liquid crystal display device (LCD), a plasma display device (PDP), a field emission display device (FED), or a display device in which the display panel 110 emits light by itself. When the display device 100 according to the embodiments of the disclosure is a self-emission display device, each of the plurality of subpixels SP may include a light emitting element.

For example, the display device 100 according to exemplary embodiments of the disclosure may be an organic light emitting diode display in which the light emitting element is implemented as an organic light emitting diode (OLED). As another example, the display device 100 according to exemplary embodiments of the disclosure may be an inorganic light emitting display device in which the light emitting element is implemented as an inorganic material-based light emitting diode. As another example, the display device 100 according to exemplary embodiments of the disclosure may be a quantum dot display device in which the light emitting element is implemented as a quantum dot which is self-emission semiconductor crystal. However, the present disclosure is not limited thereto.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction different from the first direction.

Here, the first direction may be a column direction or vertical direction, and the second direction may be a row direction or horizontal direction, without being limited thereto. The first direction may be the row direction or horizontal direction, and the second direction may be the column direction or vertical direction.

The data driving circuit 120 is a circuit configured to drive the plurality of data lines DL, and may output data signals to the plurality of data lines DL. The gate driving circuit 130 is a circuit configured to drive the plurality of gate lines GL, and may output gate signals to the plurality of gate lines GL.

The display controller 140 may be a device configured to control the operation of the data driving circuit 120 and the gate driving circuit 130. The display controller 140 may control driving timings for the plurality of data lines DL and driving timings for the plurality of gate lines GL.

The display controller 140 may supply the data driving control signal DCS to the data driving circuit 120 to control the data driving circuit 120. The display controller 140 may supply the gate driving circuit control signal GCS to the gate driving circuit 130 to control the gate driving circuit 130.

The display controller 140 may receive input image data from the host system 150 and supply image data Data to the data driving circuit 120 based on the input image data.

The data driving circuit 120 may supply data signals to the plurality of data lines DL according to the driving timing control of the display controller 140.

The data driving circuit 120 may receive digital image data Data from the display controller 140 and may convert the received image data Data into analog data signals and output them to the plurality of data lines DL.

The gate driving circuit 130 may supply gate signals to the plurality of gate lines GL according to the timing control of the display controller 140. The gate driving circuit 130 may receive a first gate voltage corresponding to a turn-on level voltage and a second gate voltage corresponding to a turn-off level voltage, along with various gate driving circuit control signals GCS, generate gate signals, and supply the generated gate signals to the plurality of gate lines GL.

For example, the data driving circuit 120 may be connected with the display panel 110 by a tape automated bonding (TAB) method or connected to a conductive pad such as a bonding pad of the display panel 110 by a chip on glass (COG) or chip on panel (COP) method or may be connected with the display panel 110 by a chip on film (COF) method.

In one or more aspects, the gate driving circuit 130 may be connected with the display panel 110 by TAB method or connected to a conductive pad such as a bonding pad of the display panel 110 by a COG or COP method or may be connected with the display panel 110 according to a COF method. Alternatively, the gate driving circuit 130 may be formed in the non-display area NA of the display panel 110 by a gate in panel (GIP) type. The gate driving circuit 130 may be disposed on the substrate SUB or may be connected to the substrate SUB. In other words, in an example where the gate driving circuit 130 is implemented by the GIP technique, the gate driving circuit 130 may be disposed in the non-display area NA of the substrate SUB. The gate driving circuit 130 may be connected to the substrate in an example where the gate driving circuit 130 is implemented by the chip-on-glass (COG) technique, the chip-on-film (COF) technique, or the like.

Meanwhile, at least one of the data driving circuit 120 and the gate driving circuit 130 may be disposed in the display area AA of the display panel 110. For example, at least one of the data driving circuit 120 and the gate driving circuit 130 may be disposed not to overlap the subpixels SP or to overlap all or some of the subpixels SP.

The data driving circuit 120 may be connected to one side (e.g., an upper or lower side) of the display panel 110. Depending on the driving scheme or the panel design scheme, data driving circuits 120 may be located in, and/or electrically connected with both the sides (e.g., both the upper and lower sides) of the display panel 110, or two or more of the four sides (e.g., the upper side, the lower side, a left side, and a right side) of the display panel 110.

The gate driving circuit 130 may be connected with one side (e.g., a left or right side) of the display panel 110, without being limited thereto. Also, the gate driving circuit 130′ may be located in, and/or electrically connected to, but not limited to, at least two of four sides or portions (e.g., the upper side, the lower side, a left side, and a right side) of the display panel 110 according to driving schemes, panel design schemes, or the like. Depending on the driving scheme or the panel design scheme, gate driving circuits 130 may be connected with both the sides (e.g., both the left and right sides) of the display panel 110, or two or more of the four sides of the display panel 110.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor, without being limited thereto.

The display controller 140 may be electrically connected to the data driving circuit 120 and the gate driving circuit 130 through a printed circuit board (PCB) or a flexible printed circuit board (FPCB).

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI). Similarly, the display controller 140 can transmit signals to, and receive signals from, the gate driving circuit 130 via one or more predefined interfaces.

Referring to FIG. 1, the display device 100 according to exemplary embodiments of the disclosure may include one or more optical areas (OA) where at least a portion of the substrate SUB has been removed.

One or more components (not shown) for providing various functions may be disposed in an area at least partially overlapping the optical area OA. The one or more components may be, e.g., an optical electronic device, a clock hand, etc.

The optical electronic device may include one or more of an image capture device, such as a camera (image sensor), and a detection sensor, such as a proximity sensor and an illuminance sensor.

For example, a capture device, such as a camera, may be positioned under a first optical area OA1, and a detection sensor may be positioned under a second optical area OA2.

The component may be positioned under the substrate SUB. The component may be positioned to at least partially overlap the optical area OA.

The first optical area OA1 and the second optical area OA2 may have various shapes, such as a circle, an ellipse, a square, a hexagon, or an octagon, without being limited thereto. The shapes of the first optical area OA1 and the second optical area OA2 may be the same or substantially same or different. The area of the first optical area OA1 may be the same as or different from the area of the second optical area OA2.

For convenience of description, an example in which the first optical area OA1 and the second optical area OA2 are circular and are identical in area is described below, but the disclosure is not limited thereto. It should be, however, understood that the scope of the present disclosure includes examples where at least one of the first optical area OA1 and the second optical area OA2 have a shape other than a circular shape, such as an ellipse, a quadrangle, a hexagon, an octagon or the like, without being limited thereto.

At least one optical area OA is positioned in the area where the substrate SUB has been removed, and the optical area OA may be a non-display area NA where no subpixel SP is disposed.

The optical area OA positioned in the display area AA is also referred to as a “hone in display (HID)” or “hole in active area (HiAA)” area.

Signal lines (e.g., data lines DL or gate lines GL) disposed on the substrate SUB may be disposed around (or bypassing) the periphery of the optical area OA.

To provide a touch sensing function as well as an image display function, the display device 100 according to exemplary embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 160 that drives and senses the touch sensor and generates and outputs touch sensing data and a touch controller 170 that may detect an occurrence of a touch or the position of the touch (or touch coordinates) using touch sensing data.

The touch sensor may include a plurality of touch electrodes. The touch sensor may further include a plurality of touch lines for electrically connecting the plurality of touch electrodes and the touch driving circuit 160.

The touch sensor may be present in a touch panel form outside the display panel 110 or may be present inside the display panel 110.

When the touch panel, in the form of a panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit 160 may supply a touch driving signal to at least one of the plurality of touch electrodes and may sense at least one of the plurality of touch electrodes to generate touch sensing data.

The touch sensing circuit can perform touch sensing. For example, the touch sensing circuit may perform touch sensing in a self-capacitance sensing scheme or a mutual-capacitance sensing scheme, without being limited thereto.

When the touch sensing circuit performs touch sensing in the self-capacitance sensing scheme, the touch sensing circuit may perform touch sensing based on capacitance between each touch electrode and the touch object (e.g., finger or pen).

According to the self-capacitance sensing scheme, each of the plurality of touch electrodes may serve both as a driving touch electrode and as a sensing touch electrode. The touch driving circuit 160 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes.

According to the mutual-capacitance sensing scheme, the plurality of touch electrodes are divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit may be implemented as separate devices or as a single device, without being limited thereto. The touch driving circuit 160 and the data driving circuit 120 may be implemented as separate devices or as a single device, without being limited thereto.

The display device 100 may further include a power supply circuit for supplying various types of power to the display driver integrated circuit and/or the touch sensing circuit.

The display device 100 according to exemplary embodiments of the disclosure may be a mobile terminal, such as a notebook computer, a smart phone or a tablet, or a monitor or television (TV) in various types, sizes, and shapes but, without limited thereto, may be a display device in various types and various sizes capable of displaying information or images.

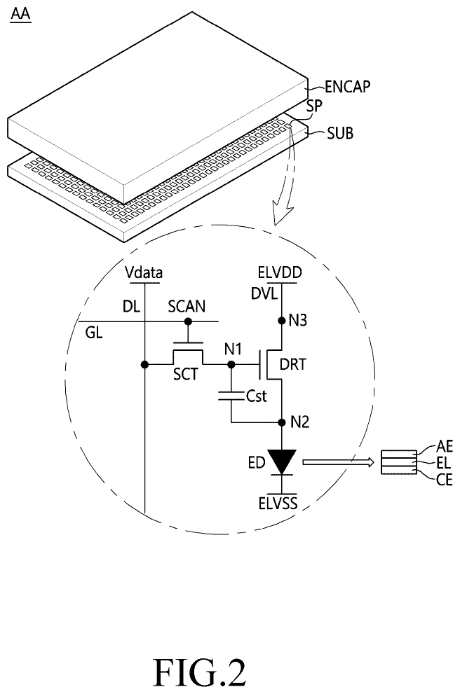

FIG. 2 is an equivalent circuit of a subpixel SP in a display panel 110 according to exemplary embodiments of the disclosure. What is identical or similar to those described with reference to FIG. 1 is omitted from the following description or briefly described below.

Referring to FIG. 2, each subpixel SP in the display area AA of the display panel 110 may include a light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT may include the first node N1 to which the data voltage Vdata may be applied, a second node N2 electrically connected with the light emitting element ED, and a third node N3 to which a high-potential common voltage ELVDD is applied from a driving voltage line DVL. The first node N1 in the driving transistor DRT may be a gate node, the second node N2 may be one of a source node and a drain node, and the third node N3 may be the other of the source node and the drain node.

The light emitting element ED1 may include an anode electrode AE which is a first electrode, a light emitting layer EL, and a cathode electrode CE which is a second electrode. The anode electrode AE may be a pixel electrode disposed in each subpixel SP and be electrically connected to the second node N2 of the driving transistor DRT of each subpixel SP. The cathode electrode CE may be a common electrode commonly disposed in the plurality of subpixels SP, and a low-potential common voltage ELVSS may be applied thereto.

For example, the light emitting layer EL may include one or more of a hole injection layer (HIL), a hole transmitting layer (HTL), an electron transmitting layer (ETL) and an electron injection layer (EIL), but the present disclosure is not limited thereto.

For example, the anode electrode AE may be a pixel electrode, and the cathode electrode CE may be a common electrode, without being limited thereto. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

For example, the light emitting element ED may be an organic light emitting diode (OLED), an inorganic light emitting diode, or a quantum dot light emitting element, without being limited thereto. In this case, when the light emitting element ED is an organic light emitting diode, the light emitting layer EL of the light emitting element ED may include an organic light emitting layer including an organic material.

The on/off of the scan transistor SCT is controlled by the scan signal SCAN, which is a gate signal applied through the gate line GL. The scan transistor SCT may switch the electrical connection between the data line DL and the first node N1 of the driving transistor DRT.

The storage capacitor Cst may be electrically connected between the first node N1 and second node N2 of the driving transistor DRT.

Each subpixel SP may have a 2T (transistor) 1C (capacitor) structure which includes two transistors DRT and SCT and one capacitor Cst as shown in FIG. 2 and, in some cases, each subpixel SP may further include one or more transistors or one or more capacitors. For example, each subpixel SP may have 3T1C, 4T1C, 5T1C, 3T2C, 4T2C, 5T2C, 6T2C, 7T1C, 7T2C, 8T2C structures, etc

The capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DRT.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel 110 to prevent or at least reduce penetration of external moisture or oxygen into the circuit elements (particularly, the light emitting element ED). The encapsulation layer ENCAP may be disposed to cover the light emitting elements ED. The encapsulation layer ENCAP may include a plurality of encapsulation layers including at least one inorganic encapsulation layer, and at least one organic encapsulation layer, without being limited thereto.

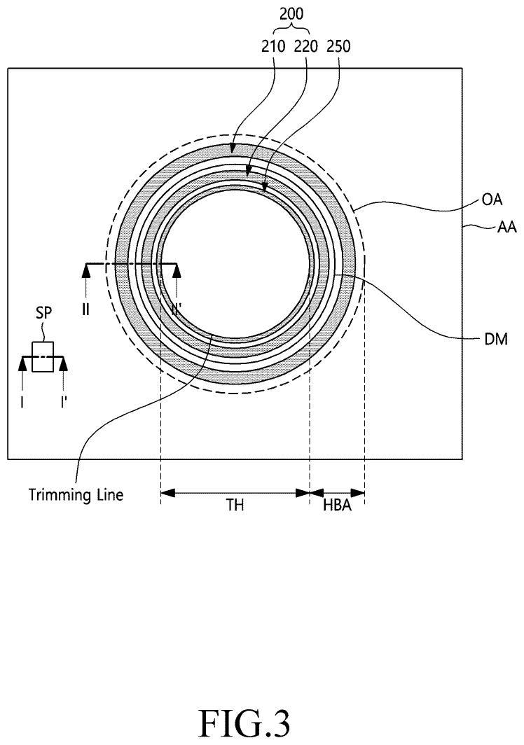

FIG. 3 is a plan view illustrating a structure of an optical area OA of a display panel 110 according to exemplary embodiments of the disclosure. What is identical or similar to those described in connection with FIGS. 1 and 2 may be omitted or briefly described below.

Referring to FIG. 3, the optical area OA is disposed in the display area AA. Pixels SP may be disposed around the optical area OA. The optical area OA may be either the first optical area OA1 or the second optical area OA2 described above.

Referring to FIG. 3, the optical area OA may include a through-hole TH and a surrounding area around the through-hole TH. The surrounding area positioned between the through hole TH and the display area AA is also referred to as a “HiAA bezel area HBA”.

A pattern area 200 or a disconnection leading structure 250 may be positioned in the HiAA bezel area HBA to prevent or at least reduce the moisture permeation path and conductive path introduced from the outside through the trimming line. A metal pattern may be disposed in the pattern area 200. The disconnection leading structure 250 may include a void portion. A subpixel for displaying an image may not be positioned in the optical area OA. In other words, the optical area OA including the “HiAA bezel area” may be a non-display area NA in which an image is not displayed.

The through-hole TH may be formed by removing the substrate along a trimming line. The shape of the through-hole TH may be circular as shown in FIG. 3, but may have various shapes, such as an oval, a square, a hexagon, or an octagon.

The pattern area 200 may include an inner pattern area 210 and an outer pattern area 220.

Referring to FIG. 3, in the HiAA bezel area HBA, a dam DM that separates two pattern areas 210 and 220 may be positioned between the inner pattern area 210 and the outer pattern area 220. The outer pattern area 220 may be positioned between the dam DM and the through-hole TH, and the inner pattern area 210 may be positioned between the display area AA and the dam DM.

A dam (not shown) may be further disposed in the inner pattern area 210 positioned between the dam DM and the display area AA. A dam (not shown) may be further disposed in the outer pattern area 220 positioned between the dam DM and the through-hole TH. The dam may be disposed to prevent or at least reduce the encapsulation layer from overflowing the display area AA.

The shape of the dam DM has a closed circuit shape (e.g., an annular shape) surrounding the through-hole TH while corresponding to the shape of the through-hole TH. The dam DM and the through-hole TH may have different closed circuit shapes, but may have the same shape but different closed circuit shapes. The dam DM and the through-hole TH may have the same shape and may be disposed to be spaced apart from each other by a predetermined interval. For example, the dam DM and the through-hole TH may have concentric shapes and may be disposed to be spaced apart from each other by a predetermined interval, without being limited thereto.

The pattern area 200 has a closed circuit shape surrounding the through-hole TH while corresponding to the shape of the through-hole TH. The pattern area 200 may have a closed circuit shape different from that of the through-hole TH, but may have a closed circuit shape having the same shape but different sizes. For example, as illustrated in FIG. 3, the pattern area 200 and the through-hole TH may have the same shape and may be disposed to be spaced apart from each other by a predetermined interval. For example, the pattern area 200 and the through-hole TH may have concentric shapes and may be disposed to be spaced apart from each other by a predetermined interval, without being limited thereto.

The disconnection leading structure 250 has a closed circuit shape surrounding the through-hole TH while corresponding to the shape of the through-hole TH. The disconnection leading structure 250 may have a closed circuit shape different from that of the through-hole TH, but may have a closed circuit shape having the same shape but different sizes. For example, as illustrated in FIG. 3, the disconnection leading structure 250 and the through-hole TH may have the same shape and may be disposed to be spaced apart from each other by a predetermined interval. For example, the disconnection leading structure 250 and the through-hole TH may have concentric shapes and may be disposed to be spaced apart from each other by a predetermined interval, without being limited thereto.

Although FIG. 3 illustrates that one disconnection leading structure 250 is disposed between the through-hole TH and the outer pattern area 220, the disclosure is not limited thereto. In other words, a plurality of disconnection leading structures 250 may be disposed at various positions in the surrounding area.

Meanwhile, the subpixel SP disposed in the display area AA may include a light emitting element. A light emitting stack (not shown) including a light emitting layer may be positioned in the display area AA. When the light emitting element is an organic light emitting element, the light emitting stack may be an organic light emitting stack including an organic material.

The light emitting stack may be disposed up to at least a partial area of the optical area OA.

Meanwhile, when moisture penetrates into the light emitting stack, defects such as dead subpixels may occur. Further, a conductive path to, e.g., the cathode disposed on the light emitting stack may be formed, causing corrosion. There is a possibility that moisture may penetrate in the area where the through-hole TH is positioned.

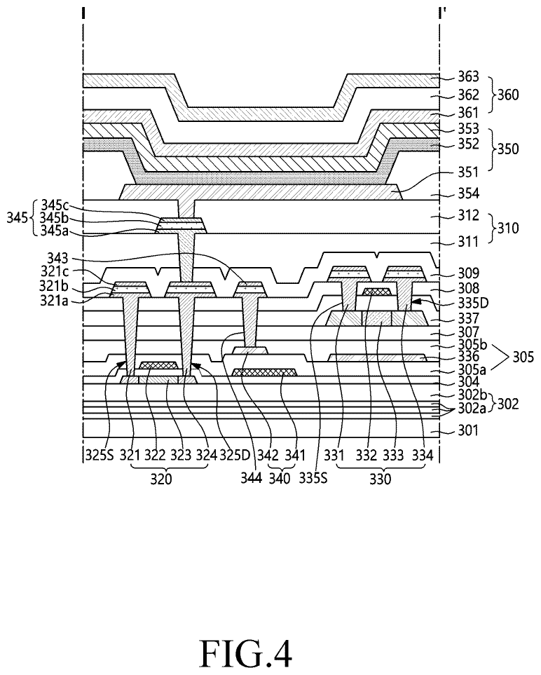

FIG. 4 is a cross-sectional view taken along line I-I′ of FIG. 3 according to one embodiment. For example, FIG. 4 is a cross-sectional view of the subpixel SP of FIG. 3. What is identical or similar to those described with reference to FIGS. 1 to 3 is omitted from the following description or briefly described below.

Referring to FIG. 4, a substrate 301 and a buffer layer 302 may be provided. The buffer layer 302 may include a multi-buffer layer 302a and a lower buffer layer 302b. A first transistor 320 may be disposed on the lower buffer layer 302b. The lower buffer layer 302b may be disposed on the multi-buffer layer 302a. A lower gate insulation film 304 may be disposed to insulate the first semiconductor layer 323 constituting the first transistor 320 from the first gate electrode 322 on the first semiconductor layer 323. A lower interlayer insulation film 305 may be disposed on the first gate electrode 322. In the lower interlayer insulation film 305, a first lower interlayer insulation film 305a and a second lower interlayer insulation film 305b may be sequentially disposed. An upper buffer layer 307 may be disposed on the lower interlayer insulation film 305.

The substrate 301 may include an insulating material. For example, the substrate 301 may include glass or plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto. The substrate 301 may have a single layer structure or a multilayer structure. For example, the substrate 301 may have a multilayer structure. The substrate 301 may include a first substrate and a second substrate, and may include an intermediate film between the first substrate and the second substrate, without being limited thereto. The first substrate and the second substrate may include the same material. For example, the first substrate and the second substrate may be polyimide (PI) substrates. The intermediate film may be a single layer or a multilayer inorganic layer of silicon nitride (SiNx) or silicon oxide (SiOx). By disposing an intermediate film between the first substrate and the second substrate, it is possible to prevent or at least reduce moisture components from penetrating through the lower first substrate into the transistor, thereby enhancing reliability of the display device.

The multi-buffer layer 302a may delay diffusion of moisture or oxygen penetrating into the substrate 301, and may be formed by alternately stacking silicon nitride (SiNx) and silicon oxide (SiOx) at least once.

The lower buffer layer 302b may protect the first semiconductor layer 323 and may block various types of defects introduced from the substrate. The lower buffer layer 302b may be formed of amorphous silicon (a-Si), silicon nitride (SiNx), silicon oxide (SiOx), or the like.

The first semiconductor layer 323 of the first thin film transistor 320 may be formed of a polycrystalline semiconductor layer, and the first semiconductor layer 323 may include a channel area, a source area, and a drain area.

The polycrystalline semiconductor layer has higher mobility than the amorphous semiconductor layer and the oxide semiconductor layer, and thus has low energy consumption power and excellent reliability. As such, the polycrystalline semiconductor layer may be used for the driving transistor.

The first gate electrode 322 may be disposed on the lower gate insulation film 304 and may be disposed to overlap the first semiconductor layer 323.

The second transistor 330 may be disposed on the upper buffer layer 307, and the light blocking layer 336 may be disposed under an area corresponding to the second transistor 330.

Referring to FIG. 4, the light blocking layer 336 may be disposed on the first lower interlayer insulation film 305a of the area corresponding to the second transistor 330, and the second semiconductor layer 333 of the second transistor 330 may be disposed on the second lower interlayer insulation film 305b and the upper buffer layer 307 to overlap the light blocking layer 336. An upper gate insulation film 337 for insulating the second gate electrode 332 and the second semiconductor layer 333 may be disposed on the second semiconductor layer 333, and then an upper interlayer insulation film 308 may be disposed on the second gate electrode 332. The second gate electrode 332 may be disposed on the upper gate insulation film 337, and the upper gate insulation film 337 may be disposed on the second semiconductor layer 333 and a portion of the upper buffer layer 307. The first gate electrode 322 and the second gate electrode 332 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

The first and second lower interlayer insulation films 305a and 305b may be formed of an inorganic layer having a higher hydrogen particle content than the upper interlayer insulation film 308. For example, the first and second lower interlayer insulation films 305a and 305b may be formed of silicon nitride (SiNx) formed by a deposition process using NH3 gas, and the upper interlayer insulation film 308 may be formed of silicon oxide (SiOx), without being limited thereto. The hydrogen particles included in the first and second lower interlayer insulation films 305a and 305b may be diffused to the polycrystalline semiconductor layer during the hydrogenation process to fill the voids in the polycrystalline semiconductor layer with hydrogen. Accordingly, the polycrystalline semiconductor layer may be stabilized, thereby preventing or at least reducing the characteristic degradation of the first transistor 320.

The second semiconductor layer 333 of the second transistor 330 may be formed after the first semiconductor layer 323 of the first transistor 320 is activated and hydrogenated, and the second semiconductor layer 333 may be formed of an oxide semiconductor. Since the second semiconductor layer 333 is not exposed to the high-temperature atmosphere of the activation and hydrogenation process of the first semiconductor layer 323, the second semiconductor layer 333 may be prevented from being damaged, or a risk of damaging the second semiconductor layer 333 is at least reduced, thereby enhancing reliability.

After the upper interlayer insulation film 308 is disposed, the first source contact hole 325S and the first drain contact hole 325D may be formed to correspond to the source and drain areas, respectively, of the first transistor 320, and the second source contact hole 335S and the second drain contact hole 335D may be formed to correspond to the source and drain areas, respectively, of the second transistor 330.

Referring to FIG. 4, the first source contact hole 325S and the first drain contact hole 325D may be formed in the first transistor 320, and the second source contact hole 335S and the second drain contact hole 335D may also be formed in the second transistor 330. Referring to FIG. 4, the first source contact hole 325S and the first drain contact hole 325D may be continuously formed from the upper interlayer insulation film 308 to the lower gate insulation film 304. The first source electrode 321 and the first drain electrode 324 corresponding to the first transistor 320, and the second source electrode 331 and the second drain electrode 334 corresponding to the second transistor 330 may be simultaneously formed, thereby reducing the number of processes for forming the respective source and drain electrodes of the first transistor 320 and the second transistor 330.

The first source and drain electrodes 321 and 324 of the first transistor 320 and the second source and drain electrodes 331 and 334 of the second transistor 330 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

The first source and drain electrodes 321 and 324 of the first transistor 320 and the second source and drain electrodes 331 and 334 of the second transistor 330 may be formed in a triple layer structure, without being limited thereto. The first source electrode 321 may sequentially include a first electrode layer 321a, a second electrode layer 321b, and a third electrode layer 321c. For example, the second electrode layer 321b may be disposed on the first electrode layer 321a, and the third electrode layer 321c may be disposed on the second electrode layer 321b.

The first electrode layer 321a, the second electrode layer 321b, and the third electrode layer 321c may include materials having relatively different etching speeds. The second electrode layer 321b may include a material having a relatively fast etching speed, and the first electrode layer 321a and the third electrode layer 321c may include a material having a relatively slow etching speed. The etching speed of the second electrode layer 321b may be relatively faster than the etching speeds of the first electrode layer 321a and the third electrode layer 321c.

For example, the second electrode layer 321b may include aluminum (Al) having a relatively fast etching speed, and the first electrode layer 321a and the third electrode layer 321c may include titanium (Ti) having a relatively slow etching speed. The first source electrode 321 may have a triple layer structure of Ti/Al/Ti, without being limited thereto.

Other source and drain electrodes may have the same structure as the first source electrode 321. Those identical or similar to what has been described with reference to the first source electrode 321 are omitted from the following description or are briefly described.

A storage capacitor 340 may be disposed between the first transistor 320 and the second transistor 330. The storage capacitor 340 may comprise a storage lower electrode 341 and a storage upper electrode 342. As illustrated in FIG. 4, the storage capacitor 340 may be formed by overlapping the storage lower electrode 341 and the storage upper electrode 342 with the first lower interlayer insulation film 305a interposed therebetween.

The storage lower electrode 341 may be positioned on the lower gate insulation film 304 and may be formed of the same material on the same layer as the first gate electrode 322. The storage upper electrode 342 may be electrically connected to the pixel circuit through the storage supply line 343. The storage upper electrode 342 may be formed of the same material on the same layer as the light blocking layer 336. The storage upper electrode 342 may be connected to the storage supply line 343. For example, the storage upper electrode 342 is exposed through the storage contact hole 344 passing through the second lower interlayer insulation film 305b, the upper buffer layer 307, the upper gate insulation film 337, and the upper interlayer insulation film 308 to be connected to the storage supply line 343. Meanwhile, the storage upper electrode 342 is spaced apart from the light blocking layer 336 as illustrated in FIG. 4, but may be integrally formed to be connected to each other. The storage supply line 343 may be formed of the same material on the same plane as the first source and drain electrodes 321 and 324 of the first transistor 320 to the second source and drain electrodes 331 and 334 of the second transistor 330, and thus the storage supply line 343 may be formed simultaneously with the first source and drain electrodes 321 and 324 of the first transistor 320 to the second source and drain electrodes 331 and 334 of the second transistor 330 through the same mask process, without being limited thereto.

A protective layer 309 may be formed on the substrate 301. For example, the protective layer 309 may be formed by depositing an inorganic insulating material such as SiNx or SiOx on the substrate 301 on which the first source and drain electrodes 321 and 324, the second source and drain electrodes 331 and 334, and the storage supply line 343 are formed.

A planarization layer 310 may be formed on the substrate 301 on which the protective layer 309 is formed. The planarization layer 310 may include a first planarization layer 311 and a second planarization layer 312. For example, the second planarization layer 312 may be disposed on the first planarization layer 311.

Specifically, the first planarization layer 311 may be disposed by fully applying an organic insulating material such as an acrylic resin on the substrate 301 on which the protective layer 309 is formed.

The protective layer 309 and the first planarization layer 311 may be disposed, and a contact hole exposing the first source electrode 321 or the first drain electrode 324 of the first transistor 320 may be formed through a photolithography process. The connecting electrode 345 may be disposed in a contact hole area exposing the first drain electrode 324.

The first planarization layer 311 and a second planarization layer 312 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The connecting electrode 345 may be a single layer or a multilayer formed of any one of molybdenum (Mo), aluminum (Al), chromium (Cr), gold (Au), titanium (Ti), nickel (Ni), neodymium (Nd), and copper (Cu), or an alloy thereof, but is not limited thereto.

The connecting electrode345 may have a triple layer structure. The connecting electrode 345 may sequentially include a first connecting electrode layer 345a, a second connecting electrode layer 345b, and a third connecting electrode layer 345c. The second connecting electrode layer 345b may be disposed on the first connecting electrode layer 345a, and the third connecting electrode layer 345c may be disposed on the second connecting electrode layer 345b.

The first connecting electrode layer 345a, the second connecting electrode layer 345b, and the third connecting electrode layer 345c may include materials having relatively different etching speeds. The second connecting electrode layer 345b may include a material having a relatively fast etching speed, and the first connecting electrode layer 345a and the third connecting electrode layer 345c may include a material having a relatively slow etching speed. The etching speed of the second connecting electrode layer 345b may be relatively faster than the etching speeds of the first connecting electrode layer 345a and the third connecting electrode layer 345c.

For example, the second connecting electrode layer 345b may include aluminum (A1) having a relatively fast etching speed, and the first connecting electrode layer 345a and the third connecting electrode layer 345c may include titanium (Ti) having a relatively slow etching speed. The connecting electrode 345 may have a triple layer structure of Ti/Al/Ti, without being limited thereto.

The second planarization layer 312 may be disposed on the connecting electrode 345, and the light emitting element 350 connected to the first transistor 320 may be disposed by forming a contact hole exposing the connecting electrode 345 in the second planarization layer 312. For example, the second planarization layer 312 may be disposed on the connecting electrode 345 and a portion of the first planarization layer 311.

The light emitting element 350 may include an anode electrode 351 connected to the first drain electrode 324 of the first transistor 320, at least one light emitting stack 352 formed on the anode electrode 351, and a cathode electrode 353 formed on the light emitting stack 352.

The light emitting stack 352 may include a light emitting layer. The light emitting stack 352 may further include a functional layer in addition to the light emitting layer. The light emitting stack 352 may include a hole injection layer, a hole transport layer, an electron transport layer, and an electron injection layer as functional layers in addition to the light emitting layer. The light emitting stack 352 may include a charge generation layer disposed between the light emitting layer and the light emitting layer in a tandem structure in which a plurality of light emitting layers overlap each other. The light emitting layer may occasionally emit light of different colors. The light emitting layers of different colors may be separately formed for each subpixel. For example, a red light emitting layer, a green light emitting layer, and a blue light emitting layer may be separately formed for each subpixel, without being limited thereto. Alternatively, a cyan light emitting layer, a magenta light emitting layer, or a yellow light emitting layer, etc may be separately formed for each subpixel, without being limited thereto. However, a common light emitting layer may be formed for each pixel to emit white light regardless of color, and color filters for distinguishing colors may be separately provided. The classifications may be divided into an RGB type (real RGB type) and white OLED (WOLED). Each of the light emitting layers may be individually formed, but the injection layer to the transport layer may be provided as a common layer to be equally disposed for each subpixel.

The anode electrode 351 may be connected to the connecting electrode 345 exposed through the contact hole penetrating the second planarization layer 312. The anode electrode 351 may be formed in a multilayer structure including a transparent conductive film and an opaque conductive film having high reflection efficiency. The transparent conductive film may be formed of a material having a relatively large work function value, such as indium-tin-oxide (ITO) or indium-zinc-oxide (IZO), and the opaque conductive film may be formed of a single layer or multilayer structure including Al, Ag, Cu, Pb, Mo, Ti, or an alloy thereof, without being limited thereto. For example, the anode electrode 351 may be formed in a structure in which a transparent conductive film, an opaque conductive film, and a transparent conductive film are sequentially stacked, or may be formed in a structure in which a transparent conductive film and an opaque conductive film are sequentially stacked. The anode electrode 351 may be disposed on the second planarization layer 312 to overlap not only the light emitting area provided by the bank 354 but also the pixel circuit area in which the first and second transistors 320 and 330 and the storage capacitor 340 are disposed, thereby increasing the light emitting area.

The light emitting stack 352 may be formed by stacking a hole transport layer, an organic light emitting layer, and an electron transport layer, in the order or in the reverse order, on the anode electrode 351. Further, the light emitting stack 352 may further include a charge generation layer and may include first and second light emitting stacks facing each other with a charge generation layer interposed therebetween.

The bank 354 may be formed to expose the anode electrode 351. The bank 354 may be formed of an organic material such as photoacrylic, and may be a translucent material, but is not limited thereto, and may be formed of an opaque material to prevent or at least reduce light interference between subpixels.

As one example, each of the anode electrode 351 and the cathode electrode 353 may comprise a metal material such as Au, W, Pt, Si, Ir, Ag, Cu, Ni, Ti, or Cr, and an alloy thereof. Alternatively, each of the anode electrode 351 and the cathode electrode 353 may include a transparent conductive material such as ITO indium tin oxide or IZO indium zinc oxide.

The cathode electrode 353 may be formed on an upper surface of the light emitting stack 352 to face the anode electrode 351 with the light emitting stack 352 interposed therebetween. When the cathode electrode 353 is applied to the front emission organic light emitting display device, the cathode electrode 353 may be formed of a transparent conductive film by thinly forming indium-tin-oxide (ITO), indium-zinc-oxide (IZO), or magnesium-silver (Mg—Ag).

An encapsulation layer 360 for protecting the light emitting element 350 may be formed on the cathode electrode 353. Due to the organic material characteristics of the light emitting stack 352, the light emitting element 350 may react with external moisture or oxygen to cause dark spots or pixel shrinkage. To prevent or at least reduce this, the encapsulation layer 360 may be disposed on the cathode electrode 353.

The encapsulation layer 360 may have a single layer structure or a multilayer structure. For example, as illustrated in FIG. 4, the encapsulation layer 360 may include a first encapsulation layer 361, a second encapsulation layer 362, and a third encapsulation layer 363. For example, the second encapsulation layer 362 may be disposed on the first encapsulation layer 361, and the third encapsulation layer 363 may be disposed on the second encapsulation layer 362.

The encapsulation layer 360 may include an inorganic film including an inorganic insulating material. The encapsulation layer 360 may include an organic film including an organic material. The encapsulation layer 360 may include an inorganic film and an organic film.

For example, the first encapsulation layer 361 and the third encapsulation layer 363 may be inorganic films, and the second encapsulation layer 362 may be organic films. Among the first encapsulation layer 361, the second encapsulation layer 362, and the third encapsulation layer 363, the second encapsulation layer 362 may be the thickest. Accordingly, the second encapsulation layer 362 may serve as a planarization layer. The first encapsulation layer 361 is also referred to as a first inorganic encapsulation layer, the second encapsulation layer 362 is also referred to as an organic encapsulation layer, and the third encapsulation layer 363 is also referred to as a second inorganic encapsulation layer.

For example, the first encapsulation layer 361 and the third encapsulation layer 363 may include an inorganic insulating material. For example, the first encapsulation layer 361 and the third encapsulation layer 363 may include an inorganic insulating material, such as silicon nitride (SiN), silicon oxide (SiO), silicon oxynitride (SiON) and aluminum oxide (AlO), without being limited thereto.

For example, the second encapsulation layer 362 may include an organic insulating material, such as acrylic resin, epoxy resin, polyimide, polyethylene and silicon oxycarbide (SiOC), without being limited thereto.

The first encapsulation layer 361 may be disposed on the cathode electrode 353 of the light emitting element 350 and may be disposed closest to the light emitting element 350. The first encapsulation layer 361 may be formed of an inorganic insulating material capable of low temperature deposition. For example, the first encapsulation layer 361 may be silicon nitride (SiNx), silicon oxide (SiOx), silicon oxynitride (SiON), or aluminum oxide (Al₂O₃), without being limited thereto. Since the first encapsulation layer 361 is deposited in a low-temperature atmosphere, the first encapsulation layer 361 may prevent or at least reduce the light emitting stack 352 including an organic material vulnerable to a high-temperature atmosphere from being damaged during the deposition process.

The second encapsulation layer 362 may be formed on the substrate 301 on which the first encapsulation layer 361 is formed. The second encapsulation layer 362 may be formed with an area smaller than that of the first encapsulation layer 361. In this case, the second encapsulation layer 362 may be formed to expose two opposite ends of the first encapsulation layer 361. The second encapsulation layer 362 may serve as a buffer to relieve stress between layers due to bending of the display device 100, and may also serve to enhance planarization performance. Further, the second encapsulation layer 362 may be referred to as a foreign object compensation layer. For example, the second encapsulation layer 362 may be an acrylic resin, an epoxy resin, polyimide, polyethylene, silicon oxycarbon (SiOC), or the like, and may be formed of an organic insulating material, without being limited thereto. For example, the second encapsulation layer 362 may be formed through an inkjet method, without being limited thereto.

The third encapsulation layer 363 may be formed on the substrate 301 on which the second encapsulation layer 362 is formed to cover the upper surface and the side surface of each of the second encapsulation layer 362 and the first encapsulation layer 361. The third encapsulation layer 363 may minimize or block or at least reduce external moisture or oxygen from penetrating into the first encapsulation layer 361 and the second encapsulation layer 362. For example, the third encapsulation layer 363 is formed of an inorganic insulating material such as silicon nitride (SiNx), silicon oxide (SiOx), silicon oxynitride (SiON), or aluminum oxide (Al₂O₃), without being limited thereto.

Materials of the first encapsulation layer 361 and the third encapsulation layer 363 may be different from each other, without being limited thereto. Alternatively, the thicknesses of the first encapsulation layer 361 and the third encapsulation layer 363 may be the same. The thicknesses of the first encapsulation layer 361 and the third encapsulation layer 363 may be different from each other. The thickness of the first encapsulation layer 361 may be larger than the thickness of the third encapsulation layer 363. Alternatively, the thickness of the third encapsulation layer 363 may be larger than the thickness of the first encapsulation layer 361.

The display device 100 may include a plurality of insulation films positioned on the substrate 301 and below the light emitting element 350. The plurality of insulation films may refer to the first buffer layer 302a, the second planarization layer 312 and insulation films positioned therebetween. The plurality of inorganic insulation films may refer to the first buffer layer 302a, the upper interlayer insulation film 308, and insulation films positioned therebetween.

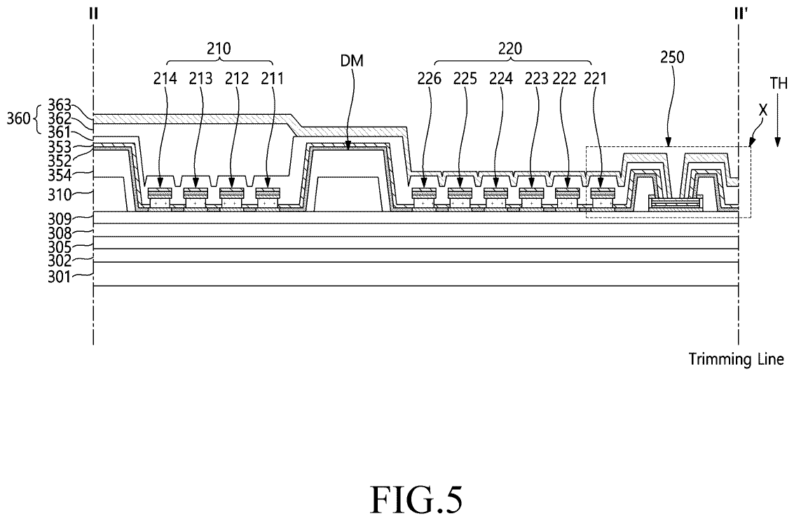

FIG. 5 is a cross-sectional view taken along line II-II′ of FIG. 3 according to one embodiment. For example, FIG. 5 is a view illustrating a cross-sectional structure of the optical area OA of FIG. 3. Those identical or similar to what has been described with reference to FIGS. 1 to 4 are omitted from the following description or are briefly described.

Referring to FIGS. 3 and 5, in the display device 100 according to exemplary embodiments of the disclosure, the optical area OA may include a through-hole TH, a display area AA surrounding the through-hole TH, and an HiAA bezel area HBA between the through-hole TH and the display area AA. In the description according to exemplary embodiments of the disclosure, the HiAA bezel area HBA may be referred to as a surrounding area.

When looking at the cross section of the surrounding area, various insulation films present in the display area AA may be disposed. For example, the buffer layer 302, the lower interlayer insulation film 305, the upper buffer layer 307, and the upper interlayer insulation film 308 may be sequentially stacked on the substrate 301.

Referring to FIGS. 3 and 5, a “dam structure” such as a dam DM may be included between the display area AA and the through-hole TH.

Such a dam structure may have a layer structure of two or more layers formed perpendicular to the substrate 301. For example, the dam structure may include a first layer formed of a planarization layer 310 and a second layer formed of a bank 354. Specifically, the dam structure may include a first layer formed of a second planarization layer 312 and a second layer formed of a bank 354. The dam structure may include a first layer formed of a second planarization layer 312, a second layer formed of a bank 354, and a third layer formed of a spacer (not shown). The dam structure may further include a first planarization layer 311 under the second planarization layer 312 or may further include another layer to have a stacked structure.

Some components constituting the light emitting element may be stacked on the dam DM. For example, the light emitting stack 352 and the cathode electrode 353 may be stacked in a shape of running over the dam DM.

Referring to FIG. 5, a pattern area 200 in which metal patterns 211, 212, 213, 214, 221, 222, 223, 224, 225, and 226 for preventing or at least reducing moisture introduced from the outside and fine cracks through a trimming line are disposed may be positioned inside and outside the dam DM. The metal patterns 211, 212, 213, 214, 221, 222, 223, 224, 225, and 226 may be disposed on the insulation film. The pattern area 200 may include an inner pattern area 210 positioned between the dam DM and the display area AA and an outer pattern area 220 positioned between the through-hole TH and the dam DM. That is, the dam DM may be disposed between the inner pattern area 210 and the outer pattern area 220.

The inner pattern area 210 may include a first metal pattern 211, a second metal pattern 212, a third metal pattern 213, and a fourth metal pattern 214, without being limited thereto. The outer pattern area 220 may include a fifth metal pattern 221, a sixth metal pattern 222, a seventh metal pattern 223, an eighth metal pattern 224, a ninth metal pattern 225, and a tenth metal pattern 226, without being limited thereto.

In FIG. 5, it is illustrated that there are six metal patterns in the outer pattern area 220 and four metal patterns in the inner pattern area 210, but the disclosure is not limited thereto and various numbers of metal patterns may be configured. For example, according to the width of the metal pattern and the arrangement interval between the metal patterns, about 2 to 15 metal patterns may be configured in the inner pattern area 210, and about 5 to 30 metal patterns may be configured in the outer pattern area 220.

The first to tenth metal patterns 211, 212, 213, 214, 221, 222, 223, 224, 225, and 226 may be formed of a metallic material and may be a single layer or multiple layers, but are not limited thereto.

The first to tenth metal patterns 211, 212, 213, 214, 221, 222, 223, 224, 225, and 226 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

For example, each metal pattern may have a structure in which metallic materials are sequentially stacked. For example, each metal pattern may comprise a second metal layer including a material having a relatively fast etching speed, and a first metal layer and a third metal layer including a material having a relatively slow etching speed. For example, each metal pattern may be a metal layer structure of a triple layer of Ti/Al/Ti. Further, each metal pattern may be a six-layer metal layer structure in which triple-layer metal layers are stacked, but are not limited thereto.

The first to tenth metal patterns 211, 212, 213, 214, 221, 222, 223, 224, 225, and 226 may be simultaneously disposed with the same material as any one of the source electrodes 321 and 331, the drain electrodes 324 and 334, and the connecting electrode 345, without being limited thereto. Further, the first to tenth metal patterns 211, 212, 213, 214, 221, 222, 223, 224, 225, and 226 may be simultaneously disposed of the same material as the source electrodes 321 and 331 and the drain electrodes 324 and 334, and may be sequentially simultaneously disposed of the same material as the connecting electrode 345.

Referring to FIG. 5, the light emitting stack 352 may be disposed to be disconnected between metal patterns. Due to the nature of the organic material, the light emitting stack 352 has high reactivity and propagation properties to moisture and oxygen, so that moisture and oxygen may be transferred to the light emitting element 350 in the display area AA. To prevent or at least reduce this, the light emitting stack 352 may be partially disconnected by the metal pattern.

The metal pattern may have a concave side surface. The light emitting stack 352 is deposited on the front surface of the display panel 110 using straightness during deposition, but the side surface of the metal pattern has a concave shape, so that the light emitting stack 352 may not be formed in a concave space, and thus the light emitting stack 352 may be disconnected.

The light emitting stack 352 may be disconnected by the metal pattern to prevent or at least reduce penetration of oxygen and moisture through the light emitting stack 352.

Referring to FIG. 5, a pattern area 200 in which metal patterns 211, 212, 213, 214, 221, 222, 223, 224, 225, and 226 for preventing or at least reducing moisture introduced from the outside and fine cracks through a trimming line are disposed may be positioned inside and outside the dam DM. The metal patterns 211, 212, 213, 214, 221, 222, 223, 224, 225, and 226 may be disposed on the insulation film. The pattern area 200 may include an inner pattern area 210 positioned between the dam DM and the display area AA and an outer pattern area 220 positioned between the through-hole TH and the dam DM. That is, the dam DM may be disposed between the inner pattern area 210 and the outer pattern area 220.

Referring to FIG. 5, a disconnection leading structure 250 may be disposed in the surrounding area. The disconnection leading structure 250 may include a void portion. The disconnection leading structure 250 may disconnect the light emitting stack 352 and the second electrode 353 which is the cathode by including the void portion. Thus, the second electrode 353 is also referred to as a cathode electrode 353. The disconnection leading structure 250 may block the conductive path by the cathode and the side permeation path by the light emitting stack.

Referring to FIG. 5, the disconnection leading structure 250 may be disposed between the dam DM and the through-hole TH. The disconnection leading structure 250 may be disposed between the outer pattern area 220 and the through-hole TH.

Referring to FIG. 5, the encapsulation layer 360 may be disposed in the surrounding area in the same manner as the display area AA. The encapsulation layer 360 may include a first encapsulation layer 361, a second encapsulation layer 362, and a third encapsulation layer 363. For example, the second encapsulation layer 362 may be disposed on the first encapsulation layer 361, and the third encapsulation layer 363 may be disposed on the second encapsulation layer 362. The first encapsulation layer 361 and the third encapsulation layer 363 may be inorganic films, and the second encapsulation layer 362 may be organic films. Among the first encapsulation layer 361, the second encapsulation layer 362, and the third encapsulation layer 363, the second encapsulation layer 362 may be the thickest.

The first encapsulation layer 361 and the third encapsulation layer 363 may be disposed in the inner pattern area 210, the dam DM, the outer pattern area 220, and the disconnection leading structure 250. The first encapsulation layer 361 may be disposed on the first to tenth metal patterns 211, 212, 213, 214, 221, 222, 223, 224, 225, and 226 of the pattern area 200 and in spaces between the metal patterns. The first encapsulation layer 361 may be disposed on the disconnection leading structure 250. The third encapsulation layer 363 may be disposed on the fifth to tenth metal patterns 221, 222, 223, 224, 225, and 226 of the outer pattern area 220 and in spaces between the metal patterns. The third encapsulation layer 363 may be disposed on the disconnection leading structure 250.

In the inner pattern area 210, the first encapsulation layer 361 may be disposed on the first to fourth metal patterns 211, 212, 213, and 214 of the inner pattern area 210 and in spaces between the metal patterns. In the outer pattern area 220, the first encapsulation layer 361 and the third encapsulation layer 363 may be disposed to contact each other. The first encapsulation layer 361 and the third encapsulation layer 363 may be disposed on the fifth to tenth metal patterns 221, 222, 223, 224, 225, and 226 of the outer pattern area 220 and in spaces between the metal patterns. The first encapsulation layer 361 and the third encapsulation layer 363 may be disposed to contact each other on the disconnection leading structure 250. In other words, the first encapsulation layer 361 and the third encapsulation layer 363 may be disposed to contact on the dam DM and disposed to extend to the through-hole TH.

The first encapsulation layer 361 and the third encapsulation layer 363 may be disposed to be exposed through the through-hole TH.

The second encapsulation layer 362 may be disposed in the inner pattern area 210. The second encapsulation layer 362 may be disposed only in a portion of an area near the dam DM, and may not be disposed in the outer pattern area 220, without being limited thereto.

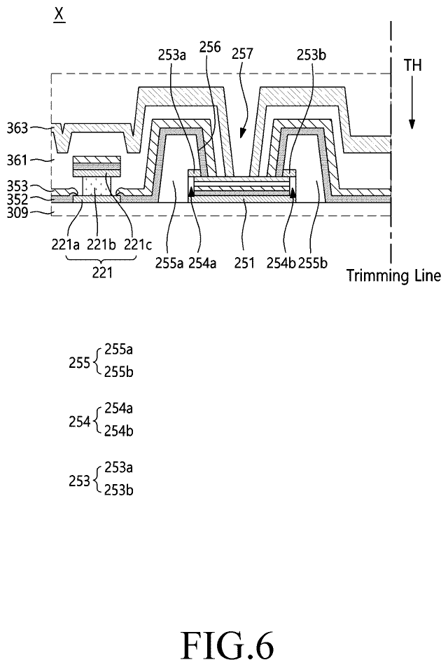

FIG. 6 is an example cross-sectional enlarged view illustrating area X of FIG. 5. For example, FIG. 6 is an enlarged cross-sectional view of the disconnection leading structure 250. Those identical or similar to what has been described with reference to FIGS. 1 to 5 are omitted from the following description or are briefly described.

Referring to FIG. 6, the disconnection leading structure 250 may include a void portion 254 at a lower portion thereof. For example, the disconnection leading structure 250 may include the void portion 254 to disconnect the light emitting stack 352. The disconnection leading structure 250 may include a first metal layer 251 disposed on the upper interlayer insulation film 308, which is an insulation film, a void portion 254 disposed on the first metal layer 251, a third metal layer 253 disposed on the void portion 254, and an organic film 255 covering the first metal layer 251, the void portion 254, and the third metal layer 253.

Referring to FIG. 6, the organic film 255 may include a first organic film 255a and a second organic film 255b that are disconnected by the groove 257. The first organic film 255a and the second organic film 255b may have a forward tapered shape.

The organic film 255 may be simultaneously formed and disposed of the same material as the planarization layer 310 or the bank 354, without being limited thereto. For example, the organic film 255 may be simultaneously formed and disposed of the same material as the first planarization layer 311, without being limited thereto. For example, the organic film 255 may be simultaneously formed and disposed of the same material as the second planarization layer 312, without being limited thereto. For example, the organic film 255 may be simultaneously formed and disposed of the same material as the bank 354, without being limited thereto.

An area connected to the groove 257 and in which the organic film 255 is not disposed may be positioned below the center of the organic film 255. For example, the first organic film 255a and the second organic film 255b may include an area where a lower portion is recessed inward. The recessed areas included in the first organic film 255a and the second organic film 255b may be disposed to face each other. The recessed area may be referred to as an undercut area. The void portion 254 may be a portion of an area where the organic film 255 is not disposed.

Referring to FIG. 6, the first metal layer 251 may be disposed below the center of the organic film 255 in an area where the organic film 255 is not disposed. The first metal layer 251 may be disposed on the upper interlayer insulation film 308 with the width equal to the width of the area where the organic film 255 is not disposed. The first metal layer 251 may be disposed on the lower surface of the undercut area included in the organic film 255. For example, the first metal layer 251 may be disposed to extend to the recessed areas of the first organic film 255a and the second organic film 255b. Similarly, the 3a-th metal layer 253a and the 3b-th metal layer 253b may be disposed to extend to the recessed areas of the first organic film 255a and the second organic film 255b.

Referring to FIG. 6, the void portion 254 may be disposed on the first metal layer 251. The void portion 254 may be disposed between the first metal layer 251 and the third metal layer 253. The organic film 255 may cover the first metal layer 251, the void portion 254, and the third metal layer 253. The void portion 254 may be disposed in the area where the organic film 255 is not disposed. The void portion 254 may be disposed on the upper surface of the undercut area included in the organic film 255.

The void portion 254 may include a first void portion 254a disposed on a side of the first organic film 255a and a second void portion 254b disposed on a side of the second organic film 255b. For example, the first void portion 254a may be disposed in the undercut area provided in the first organic film 255a. The second void portion 254b may be disposed in the undercut area provided in the second organic film 255b.

The void portion 254 may be formed by etching the second metal layer 252 disposed between the first metal layer 251 and the third metal layer 253. The process of forming the void portion 254 is described below in detail.

The width of the first void portion 254a and the width of the second void portion 254b may be the same as each other.

Referring to FIG. 6, the third metal layer 253 may be disposed on the first metal layer 251 to overlap the first metal layer 251. In this case, the third metal layer 253 may be disposed to be spaced apart from the first metal layer 251. The third metal layer 253 may be disposed under the organic film 255 in the area where the organic film 255 is not disposed. The third metal layer 253 may be disposed on the upper surface of the undercut area included in the organic film 255.

The third metal layer 253 may include a 3a-th metal layer 253a disposed on the side of the first organic film 255a and a 3b-th metal layer 253b disposed on the side of the second organic film 255b. The 3a-th metal layer 253a and the 3b-th metal layer 253b may be disposed to be spaced apart from each other with the groove 257 interposed therebetween. For example, the 3a-th metal layer 253a may be disposed on the upper surface of the undercut area provided in the first organic film 255a. The 3b-th metal layer 253b may be disposed on the upper surface of the undercut area provided in the second organic film 255b. The first void portion 254a may be disposed between the first metal layer 251 and the 3a-th metal layer 253a, and the second void portion 254b may be disposed between the first metal layer 251 and the 3b-th metal layer 253b.

The width of the 3a-th metal layer 253a and the width of the 3b-th metal layer 253b may be the same as each other. The width of the 3a-th metal layer 253a may be larger than the width of the first void portion 254a. The width of the 3b-th metal layer 253b may be larger than the width of the second void portion 254b.

The structures of the first metal layer 251 and the third metal layer 253 included in the disconnection leading structure 250 may be formed by etching the second metal layer 252 in a structure in which the first metal layer 251, the second metal layer 252, and the third metal layer 253 are stacked.

The first metal layer 251, the second metal layer 252, and the third metal layer 253 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but are not limited thereto.

The first metal layer 251, the second metal layer 252, and the third metal layer 253 may include materials having relatively different etching speeds. The second metal layer 252 may include a material having a relatively fast etching speed, and the first metal layer 251 and the third metal layer 253 may include a material having a relatively slow etching speed. The etching speed of the second metal layer 252 may be relatively faster than the etching speeds of the first metal layer 251 and the third metal layer 253. Thus, the structures of the first metal layer 251 and the third metal layer 253 may be formed by etching the second metal layer 252 including a material having a relatively fast etching speed than that of the first metal layer 251 and the third metal layer 253.

For example, the second metal layer 252 may include aluminum (Al) having a relatively fast etching speed, and the first metal layer 251 and the third metal layer 253 may include titanium (Ti) having a relatively slow etching speed, without being limited thereto. That is, the first to third metal layers 251, 252, 253 may have a triple layer structure of Ti/Al/Ti. Since the etching speed of the second metal layer 252 is sufficiently faster than the etching speeds of the first metal layer 251 and the third metal layer 253, the whole or part of the second metal layer 252 may be etched during etching to form the void portion 254.

The stacked structure of the first metal layer 251, the second metal layer 252, and the third metal layer 253 may be simultaneously disposed of the same material as the source electrodes 321 and 331 and the drain electrodes 324 and 334. For example, the first metal layer 251, the second metal layer 252, and the third metal layer 253 may be sequentially stacked, in the first source electrode 321, the first electrode layer 321a, the second electrode layer 321b, and the third electrode layer 321c may be sequentially stacked, the first metal layer 251 and the first electrode layer 321a may include the same material, the second metal layer 252 and the second electrode layer 321b may include the same material, and the third metal layer 253 and the third electrode layer 321c may include the same material, without being limited thereto.

The second metal layer 252 may be simultaneously disposed of the same material as the second electrode layer 321b. In other words, the thickness of the second metal layer 252 may be identical to the thickness of the second electrode layer 321b. Since the void portion 254 is formed by etching the second metal layer 252, the height of the void portion 254 may be the same as the thickness of the second electrode layer 321b.

Since the other source and drain electrodes may have the same structure as the first source electrode 321, the first metal layer 251, the second metal layer 252, and the third metal layer 253 may have the same stacked structure and the same material as the other source and drain electrodes.

The stacked structure of the first metal layer 251, the second metal layer 252, and the third metal layer 253 may be simultaneously disposed of the same material as the connecting electrode 345. For example, the first metal layer 251, the second metal layer 252, and the third metal layer 253 may be sequentially stacked, in the connecting electrode 345, the first connecting electrode layer 345a, the second connecting electrode layer 345b, and the third connecting electrode layer 345c may be sequentially stacked, the first metal layer 251 and the first connecting electrode layer 345a may include the same material, the second metal layer 252 and the second connecting electrode layer 345b may include the same material, and the third metal layer 253 and the third connecting electrode layer 345c may include the same material. For example, the first metal layer 251 and the first connecting electrode layer 345a may be simultaneously disposed, the second metal layer 252 and the second connecting electrode layer 345b may be simultaneously disposed, and the third metal layer 253 and the third connecting electrode layer 345c may be simultaneously disposed.

The second metal layer 252 may be simultaneously disposed of the same material as the second connecting electrode layer 345b. In other words, the thickness of the second metal layer 252 and the thickness of the second connecting electrode layer 345b may be the same as each other. Since the void portion 254 is formed by etching the second metal layer 252, the height of the void portion 254 may be the same as the thickness of the second connecting electrode layer 345b.

Referring to FIG. 6, a fifth metal pattern 221 is disposed adjacent to the disconnection leading structure 250. Since the fifth metal pattern 221 includes the same configuration as other metal patterns, the fifth metal pattern 221 is described below in detail.

The fifth metal pattern 221 may have a structure in which the first metal pattern layer 221a, the second metal pattern layer 221b, and the third metal pattern layer 221c are sequentially stacked. The second metal pattern layer 221b may be disposed on the first metal pattern layer 221a, and the third metal pattern layer 221c may be disposed on the second metal pattern layer 221b.

The side surface of the fifth metal pattern 221 may have a concave shape. The concave portion of the fifth metal pattern 221 may refer to a recess formed to be concave further inside than the side portions of the first metal pattern layer 221a and the third metal pattern layer 221c by removing a portion of the second metal pattern layer 221b. In other words, the side portion of the second metal pattern layer 221b may be disposed inside as compared with the side portion of the first metal pattern layer 221a and the side portion of the third metal pattern layer 221a. For example, a width of the second metal pattern layer 221b may be smaller than that of the first metal pattern layer 221a and the third metal pattern layer 221c.

The fifth metal pattern 221 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but is not limited thereto.

The first metal pattern layer 221a, the second metal pattern layer 221b, and the third metal pattern layer 221c may include materials having relatively different etching speeds. The second metal pattern layer 221b may include a material having a relatively fast etching speed, and the first metal pattern layer 221a and the third metal pattern layer 221c may include a material having a relatively slow etching speed. The etching speed of the second metal pattern layer 221b may be relatively faster than the etching speeds of the first metal pattern layer 221a and the third metal pattern layer 221c.

For example, the second metal pattern layer 221b may include aluminum (Al) having a relatively fast etching speed, and the first metal pattern layer 221a and the third metal pattern layer 221c may include titanium (Ti) having a relatively slow etching speed. The fifth metal pattern 221 may have a triple layer structure of Ti/Al/Ti, without being limited thereto.

The fifth metal pattern 221 may be simultaneously disposed of the same material as the source electrodes 321 and 331 and the drain electrodes 324 and 334. For example, the first metal pattern layer 221a and the first electrode layer 321a may include the same material, the second metal pattern layer 221b and the second electrode layer 321b may include the same material, and the third metal pattern layer 221c and the third electrode layer 321c may include the same material.

The fifth metal pattern 221 may be simultaneously disposed of the same material as the connecting electrode 345. For example, the first metal pattern layer 221a and the first connecting electrode layer 345a may include the same material, the second metal pattern layer 221b and the second connecting electrode layer 345b may include the same material, and the third metal pattern layer 221c and the third connecting electrode layer 345c may include the same material.

Referring to FIG. 6, the light emitting stack 352 may be disposed on the disconnection leading structure 250. The light emitting stack 352 may be disposed on the fifth metal pattern 221.

The light emitting stack 352 may be disposed along the shape of the organic film 255. The light emitting stack 352 may be disposed along the inclined surface 256 of the organic film 255 where the groove 257 is formed. The light emitting stack 352 may be disposed to be disconnected by the void portion 254 disposed in the disconnection leading structure 250. In other words, the light emitting stack 352 may be disconnected from the void portion 254 and disposed on the first metal layer 251. The light emitting stack 352 disposed to be disconnected on the first metal layer 251 may be referred to as a light emitting stack pattern.

Referring to FIG. 6, the second electrode 353 may be disposed on the disconnection leading structure 250. The second electrode 353 may be disposed on the fifth metal pattern 221.

The second electrode 353 may be disposed on the light emitting stack 352. The second electrode 353 may be disposed along the light emitting stack 352 disposed on the side surface 256 of the organic film 255 where the groove 257 is formed. The second electrode 353 may be disposed to be disconnected by the void portion 254 disposed in the disconnection leading structure 250. In other words, the second electrode 353 may be disconnected from the void portion 254 and disposed on the light emitting stack pattern. The second electrode 353 disposed to be disconnected on the light emitting stack pattern may be referred to as a second electrode pattern.

Referring to FIG. 6, a first encapsulation layer 361, which is a first inorganic encapsulation layer, may be disposed on the disconnection leading structure 250. The first encapsulation layer 361 may be disposed on the fifth metal pattern 221.

The first encapsulation layer 361 may be disposed on the second electrode 353. The first encapsulation layer 361 may be disposed along the second electrode 353 disposed on the side surface 256 of the organic film 255 where the groove 257 is formed. The first encapsulation layer 361 may be disposed to be disconnected by the void portion 254 disposed in the disconnection leading structure 250. In other words, the first encapsulation layer 361 may be disconnected from the void portion 254 and disposed on the second electrode pattern. The first encapsulation layer 361 disposed to be disconnected on the second electrode pattern may be referred to as a first inorganic encapsulation layer pattern.

Referring to FIG. 6, a third encapsulation layer 363, which is a second inorganic encapsulation layer, may be disposed on the disconnection leading structure 250. The third encapsulation layer 363 may be disposed on the fifth metal pattern 221.

The third encapsulation layer 363 may be disposed on the first encapsulation layer 361. The third encapsulation layer 363 may be disposed along the first encapsulation layer 361 disposed on the side surface 256 of the organic film 255 where the groove 257 is formed. The third encapsulation layer 363 may be disposed adjacent to the void portion 254 disposed in the disconnection leading structure 250. In other words, the third encapsulation layer 363 may be disposed at a lower portion of the third metal layer 253. The third encapsulation layer 363 may be disposed on the first inorganic encapsulation layer pattern. The third encapsulation layer 363 disposed on the first inorganic encapsulation layer pattern may be referred to as a third inorganic encapsulation layer pattern.

Referring to FIG. 6, the void portion 254 may be disposed between the organic film 255 and the light emitting stack pattern, the second electrode pattern, and the first inorganic encapsulation layer pattern.

Referring to FIG. 6, the second electrode 353 may be further disconnected by the concave side surface of the fifth metal pattern 221, but may contact the first metal pattern layer 221a of the fifth metal pattern 221. In other words, the second electrode 353 and the first metal pattern layer 221a may be electrically connected to each other.

On the other hand, the second electrode 353 may be disconnected by the void portion 254 disposed in the disconnection leading structure 250, and the second electrode pattern may be disposed on the light emitting stack pattern. Further, the first inorganic encapsulation layer pattern may be disposed between the second electrode 353 and the second electrode pattern to be electrically disconnected.

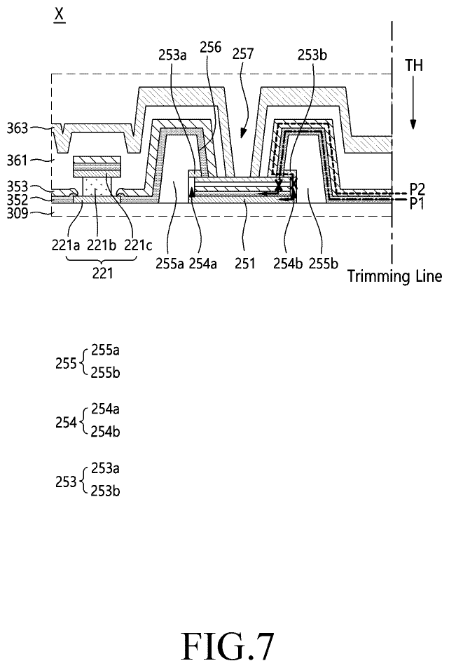

FIG. 7 is a view illustrating a moisture permeation path and a conductive path in a disconnection leading structure 250 as illustrated in FIG. 6. What is identical or similar to those described with reference to FIGS. 1 to 6 is omitted from the following description or briefly described below.

In general, the light emitting stack 352 and the second electrode 353 disposed in the display area AA may extend to the through-hole TH. The light emitting stack 352 may be a moisture permeation path P1 of moisture introduced from the outside. In other words, when the light emitting stack 352 is disposed to extend from the display area AA to the through-hole TH, moisture may penetrate into light emitting element 350 of the display area through the moisture permeation path P1. Further, the second electrode 353 may be a conductive path P2 such as of static electricity generated from the outside. In other words, when the second electrode 353 is disposed to extend from the display area AA to the through-hole TH, a high voltage caused by static electricity that may be generated in a process through the conductive path P2 may penetrate into light emitting element 350 of the display area.

The disconnection leading structure 250 may include a void portion 254 at a lower portion thereof. Referring to FIG. 7, the disconnection leading structure 250 may include a void portion 254 to disconnect the light emitting stack 352. That is, the light emitting stack 352 may be disposed to be disconnected by the void portion 254 disposed in the disconnection leading structure 250. In other words, the moisture permeation path P1 of moisture introduced from the outside along the light emitting stack 352, which is the moisture permeation path P1, may be cut off as the light emitting stack 352 is disconnected by the void portion 254 of the disconnection leading structure 250.

Referring to FIG. 7, the disconnection leading structure 250 may include a void portion 254 to disconnect the second electrode 353. That is, the second electrode 353 may be disposed to be disconnected by the void portion 254 disposed in the disconnection leading structure 250. In other words, the conductive path P2 of the high voltage introduced from the outside along the second electrode 353, which is the conductive path P2, may be cut off as the second electrode 353 is disconnected by the void portion 254 of the disconnection leading structure 250.

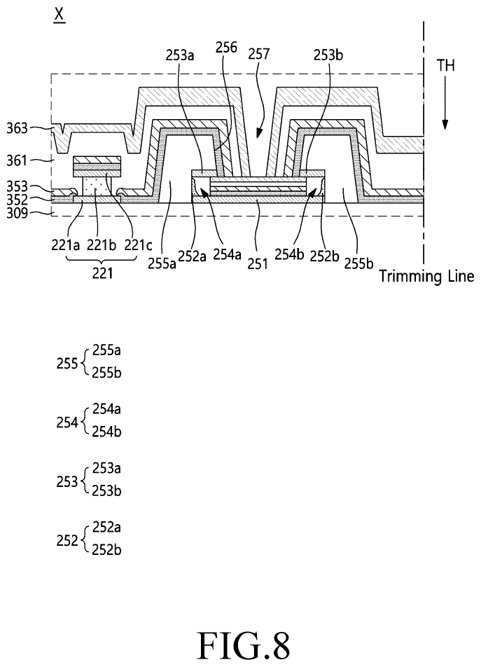

FIG. 8 is another example cross-sectional enlarged view illustrating area X of FIG. 5. For example, FIG. 8 is another example enlarged cross-sectional view of the disconnection leading structure 250. What is identical or similar to those described with reference to FIGS. 1 to 7 is omitted from the following description or briefly described below.

Referring to FIG. 8, the disconnection leading structure 250 may further include a second metal layer 252 pattern disposed between the void portion 254 and the organic film 255. The second metal layer 252 pattern may be included in the undercut area of the organic film 255. The second metal layer 252 pattern may be a pattern in which a portion of the second metal layer 252 is not etched when the void portion 254 is formed.

The void portion 254 may include a first void portion 254a disposed on a side of the first organic film 255a and a second void portion 254b disposed on a side of the second organic film 255b. The second metal layer 252 pattern may include a 2a-th metal layer 252a pattern disposed on the side of the first organic film 255a and a 2b-th metal layer 252b pattern disposed on the side of the second organic film 255b. The 2a-th metal layer 252a pattern may be disposed between the first void portion 254a and the first organic film 255a. The 2b-th metal layer 252b pattern may be disposed between the second void portion 254b and the second organic film 255b.

In this case, the width of the first void portion 254a and the width of the second void portion 254b may be the same as each other. The width of the 3a-th metal layer 253a and the width of the 3b-th metal layer 253b may be the same as each other. The width of the 3a-th metal layer 253a may be larger than the width of the first void portion 254a. The width of the 3b-th metal layer 253b may be larger than the width of the second void portion 254b.

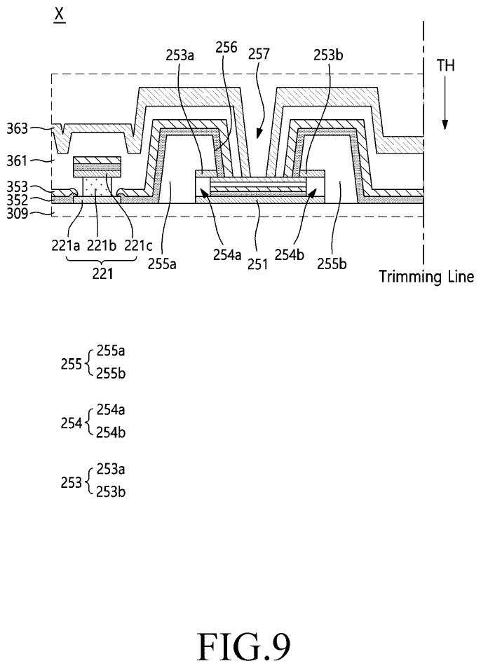

FIG. 9 is another example cross-sectional enlarged view illustrating area X of FIG. 5. For example, FIG. 9 is another example enlarged cross-sectional view of the disconnection leading structure 250. What is identical or similar to those described with reference to FIGS. 1 to 8 is omitted from the following description or briefly described below.

Referring to FIG. 9, the disconnection leading structure 250 may include a 3a-th metal layer 253a and a 3b-th metal layer 253b having different widths. For example, the width of the 3a-th metal layer 253a disposed on the first organic film 255a may be smaller than the width of the 3b-th metal layer 253b disposed on the second organic film 255b. The width of the 3a-th metal layer 253a may be larger than the width of the first void portion 254a. The width of the 3b-th metal layer 253b may be larger than the width of the second void portion 254b. For another example, the width of the 3b-th metal layer 253b disposed on the second organic film 255 may be smaller than the width of the 3a-th metal layer 253a disposed on the first organic film 255a.

Referring to FIG. 9, the disconnection leading structure 250 may include a first void portion 254a and a second void portion 254b having different widths. For example, the width of the first void portion 254a disposed in the first organic film 255a may be smaller than the width of the second void portion 254b disposed in the second organic film 255b. The width of the 3a-th metal layer 253a may be larger than the width of the first void portion 254a. The width of the 3b-th metal layer 253b may be larger than the width of the second void portion 254b. For another example, the width of the second void portion 254b disposed in the second organic film 255b may be smaller than the width of the first void portion 254a disposed in the first organic film 255a.

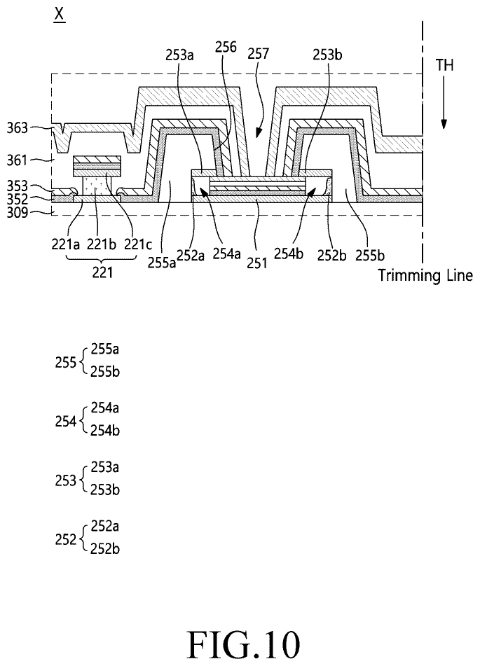

FIG. 10 is another example cross-sectional enlarged view illustrating area X of FIG. 5. For example, FIG. 10 is another example enlarged cross-sectional view of the disconnection leading structure 250. Those identical or similar to what has been described with reference to FIGS. 1 to 9 are omitted from the following description or are briefly described.

Referring to FIG. 10, the disconnection leading structure 250 may further include a second metal layer 252 pattern disposed between the void portion 254 and the organic film 255.

The second metal layer 252 pattern may be included in the undercut area of the organic film 255. The second metal layer 252 pattern may be a pattern in which a portion of the second metal layer 252 is not etched when the void portion 254 is formed.

The void portion 254 may include a first void portion 254a disposed on a side of the first organic film 255a and a second void portion 254b disposed on a side of the second organic film 255b. The second metal layer 252 pattern may include a 2a-th metal layer 252a pattern disposed on the side of the first organic film 255a and a 2b-th metal layer 252b pattern disposed on the side of the second organic film 255b. The 2a-th metal layer 252a pattern may be disposed between the first void portion 254a and the first organic film 255a. The 2b-th metal layer 252b pattern may be disposed between the second void portion 254b and the second organic film 255b.

Referring to FIG. 10, the disconnection leading structure 250 may include a 3a-th metal layer 253a and a 3b-th metal layer 253b having different widths. For example, the width of the 3a-th metal layer 253a disposed on the first organic film 255a may be smaller than the width of the 3b-th metal layer 253b disposed on the second organic film 255b. The width of the 3a-th metal layer 253a may be larger than the width of the first void portion 254a. The width of the 3b-th metal layer 253b may be larger than the width of the second void portion 254b. For another example, the width of the 3b-th metal layer 253b disposed on the second organic film 255 may be smaller than the width of the 3a-th metal layer 253a disposed on the first organic film 255a.

Referring to FIG. 10, the disconnection leading structure 250 may include a first void portion 254a and a second void portion 254b having different widths. For example, the width of the first void portion 254a disposed in the first organic film 255a may be smaller than the width of the second void portion 254b disposed in the second organic film 255b. The width of the 3a-th metal layer 253a may be larger than the width of the first void portion 254a. The width of the 3b-th metal layer 253b may be larger than the width of the second void portion 254b. For another example, the width of the second void portion 254b disposed in the second organic film 255b may be smaller than the width of the first void portion 254a disposed in the first organic film 255a.

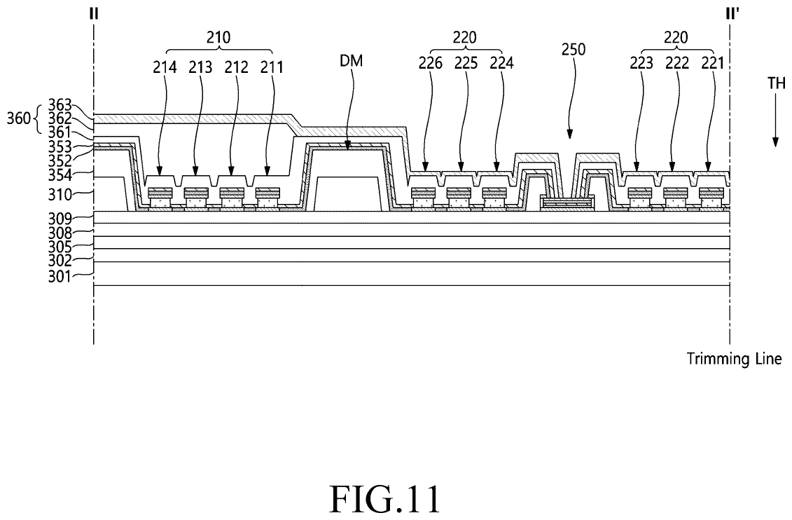

FIG. 11 is another cross-sectional view taken along line II-II′ of FIG. 3. For example, FIG. 11 is a view illustrating another example of a cross-sectional structure of the optical area OA of FIG. 3. What is identical or similar to those described with reference to FIGS. 1 to 10 is omitted from the following description or briefly described below.

Referring to FIG. 11, a disconnect induction structure 250 may be disposed in a surrounding area. The disconnection leading structure 250 may be disposed between the dam DM and the through-hole TH. The outer pattern area 220 may be positioned between the dam DM and the disconnection leading structure 250. The disconnection leading structure 250 may be disposed inside the outer pattern area 220. In other words, a portion of the outer pattern area 220 may be disposed between the dam DM and the disconnection leading structure 250, and another portion of the outer pattern area 220 may be disposed between the disconnection leading structure 250 and the through-hole TH.

As the disconnection leading structure 250 is disposed inside the outer pattern area 220, it is possible to block the moisture permeation path and the conductive path that are not blocked by the outer pattern area 220.

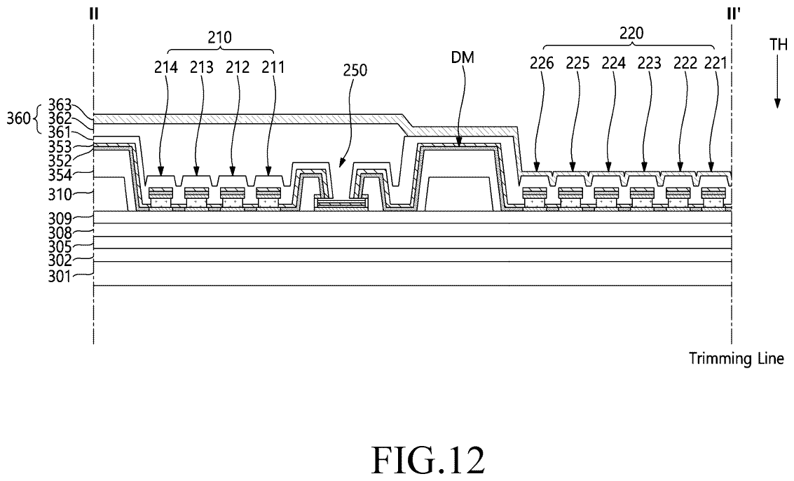

FIG. 12 is another cross-sectional view taken along line II-II′ of FIG. 3 according to one embodiment. For example, FIG. 12 is a view illustrating another example of a cross-sectional structure of the optical area OA of FIG. 3. What is identical or similar to those described with reference to FIGS. 1 to 11 is omitted from the following description or briefly described below.

Referring to FIG. 12, a disconnect induction structure 250 may be disposed in a surrounding area. The disconnection leading structure 250 may be disposed between the outer pattern area 210 and the dam DM.

Referring to FIG. 12, in the inner pattern area 210, the first encapsulation layer 361 may be disposed to be spaced apart from the third encapsulation layer 363 and may be disposed to contact the second encapsulation layer 362. The second encapsulation layer 362 may be disposed between the first encapsulation layer 361 and the third encapsulation layer 363. Accordingly, the second inorganic encapsulation layer pattern may not be disposed on the first inorganic encapsulation layer pattern in the disconnection leading structure 250. In other words, the inorganic encapsulation layer, which is the second encapsulation layer 362, may be disposed on the first inorganic encapsulation layer pattern in the disconnection leading structure 250.

For example, the second encapsulation layer 362 may be disposed in the inner pattern area 210. The second encapsulation layer 362 may be disposed only in a portion of an area near the dam DM, and may not be disposed in the outer pattern area 220, without being limited thereto.

As the disconnection leading structure 250 is disposed between the inner pattern area 210 and the dam DM, it is possible to block the moisture permeation path and the conductive path that are not blocked by the outer pattern area 220.

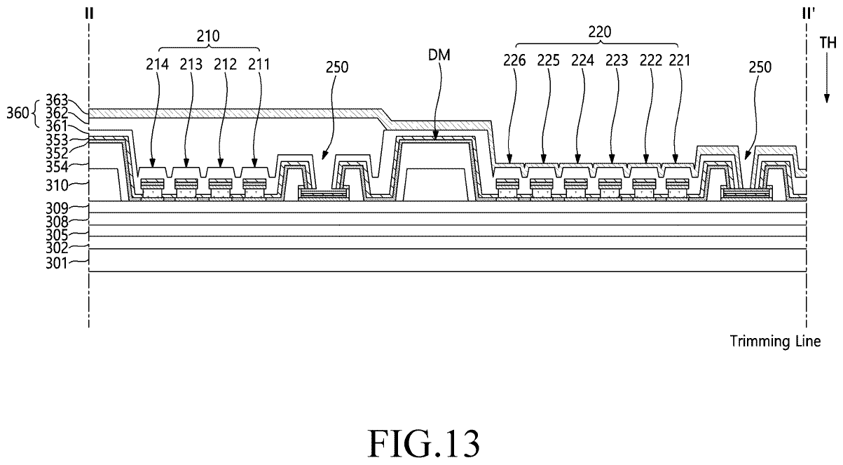

FIG. 13 is another cross-sectional view taken along line II-II′ of FIG. 3. For example, FIG. 13 is a view illustrating another example of a cross-sectional structure of the optical area OA of FIG. 3. Those identical or similar to what has been described with reference to FIGS. 1 to 12 are omitted from the following description or are briefly described.

Referring to FIG. 13, a disconnect induction structure 250 may be disposed in a surrounding area. The disconnection leading structure 250 may be disposed between the outer pattern area 210 and the dam DM, and between the outer pattern area 220 and the through-hole TH.

Referring to FIG. 13, in the inner pattern area 210, the first encapsulation layer 361 may be disposed to be spaced apart from the third encapsulation layer 363 and may be disposed to contact the second encapsulation layer 362. The second encapsulation layer 362 may be disposed between the first encapsulation layer 361 and the third encapsulation layer 363. Accordingly, the second inorganic encapsulation layer pattern may not be disposed on the first inorganic encapsulation layer pattern in the disconnection leading structure 250 disposed between the inner pattern area 210 and the dam DM. In other words, the inorganic encapsulation layer, which is the second encapsulation layer 362, may be disposed on the first inorganic encapsulation layer pattern in the disconnection leading structure 250.

As the disconnection leading structure 250 is disposed between the inner pattern area 210 and the dam DM, and between the outer pattern area 220 and the through-hole TH, the moisture permeation path and the conductive path may be more effectively blocked.

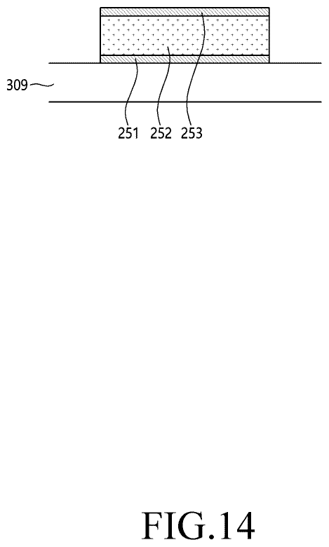

FIGS. 14 to 18 are views illustrating a process of forming a disconnection leading structure 250 of a display panel according to exemplary embodiments of the disclosure. What is identical or similar to those described with reference to FIGS. 1 to 13 is omitted from the following description or briefly described below.

First, as shown in FIG. 14, a plurality of metal layers may be patterned on the insulation film to form a stacked structure. The first metal layer 251, the second metal layer 252, and the third metal layer 253 may be sequentially stacked in the plurality of metal layers. For example, the second metal layer 252 may be disposed between the first metal layer 251 and the third metal layer 253. The stacked structure of the first metal layer 251, the second metal layer 252, and the third metal layer 253 may be simultaneously formed of the same material as the first source electrode 321 and the first drain electrode 324 of the first transistor 320. For example, the stacked structure of the metal layers may be a triple layer structure of Ti/Al/Ti. In this case, the thickness of the second metal layer 252 may be 4000 Å to 8000 Å.

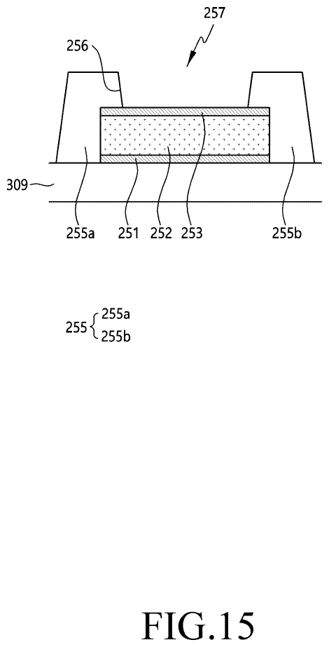

Then, as illustrated in FIG. 15, an organic film 255 including a groove 257 may be formed to cover a portion of a plurality of metal layers. The organic film 255 may be simultaneously formed of the same material as the first planarization layer 311. The organic film 255 may be formed to cover a side surface of the first metal layer 251, a side surface of the second metal layer 252, a side surface and a portion of the upper surface of the third metal layer. The organic film 255 may have a forward tapered shape including an inclined surface 256 where the groove 257 is formed. The organic film 255 may include a first organic film 255a and a second organic film 255b that are disconnected by the groove 257.

After the first planarization layer 311 is formed, a connecting electrode material may be deposited on the first planarization layer 311 to form a connecting electrode 345 connecting the first transistor 320 and the first electrode 351 of the light emitting element 350.

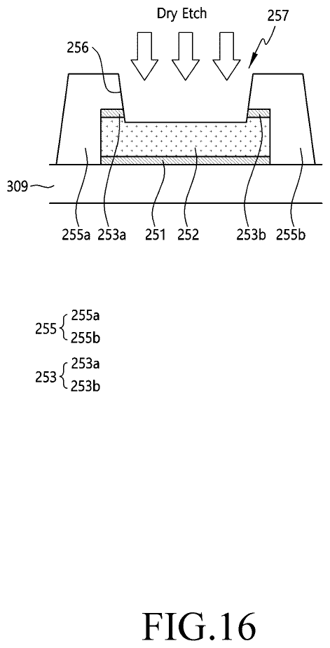

Then, as illustrated in FIG. 16, a portion of the third metal layer 253 and a portion of the second metal layer 252 exposed to the groove 257 may be etched by performing a dry etching process. The dry etching process is a process of etching the connecting electrode material to form the connecting electrode 345 on the first planarization layer 311. In other words, a portion of the second metal layer 252 and the third metal layer 253 exposed to the groove 257 may be etched during the dry etching process for forming the connecting electrode 345.

After the connecting electrode 345 is formed, a second planarization layer 312 may be formed. A developing process for forming the second planarization layer 312 may be performed. In this case, a portion of the second metal layer 252 may be additionally etched while developing the second planarization layer 312.

After the second planarization layer 312 is formed, a first electrode material may be deposited on the second planarization layer 312.

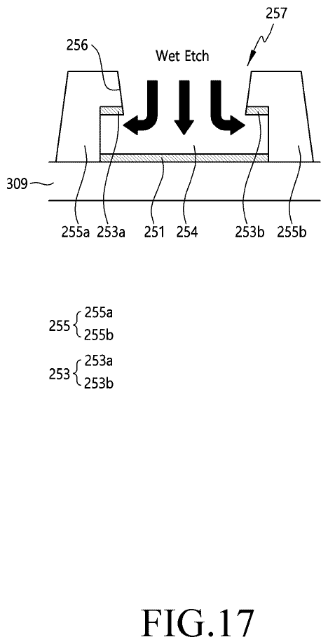

Then, as illustrated in FIG. 17, the remaining portion of the second metal layer 252 may be etched by performing a wet etching process. The wet etching process is a process of etching a first electrode material to form the first electrode 351 on the second planarization layer 312. In other words, the remaining portion of the second metal layer 252 may be etched while the wet etching process for forming the first electrode 351 is performed.

After the first electrode 511 is formed, a bank 354 may be formed to cover a portion of the first electrode 511. A developing process for forming the bank 354 may be performed. In this case, the remaining portion of the second metal layer 252 may be etched while developing the bank 354.

Accordingly, an area connected to the groove 257 and removed by etching the second electrode 353 may be formed under the center of the organic film 255. In other words, the void portion 254, which is the area where the organic film 255 is not disposed, may be formed.

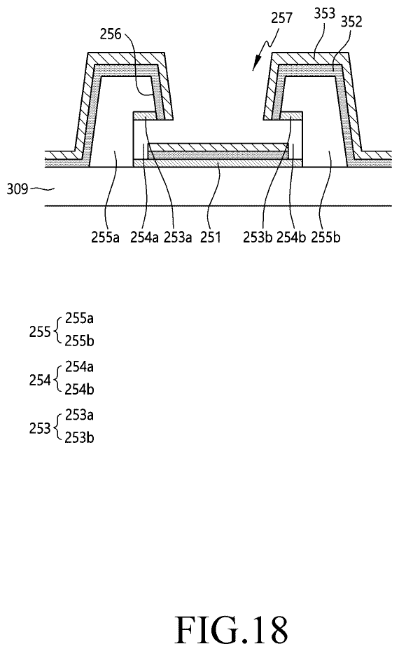

Then, as illustrated in FIG. 18, the light emitting stack 352 and the second electrode 353 may be sequentially formed. The light emitting stack 352 and the second electrode 353 may be disconnected by the void portion 254. In other words, a light emitting stack pattern disconnected from the light emitting stack 352 and a second electrode pattern disconnected from the second electrode 353 may be formed on the first metal layer 251.

Exemplary embodiments of the disclosure described above are briefly described below.

According to exemplary embodiments of the disclosure, there may be provided a display device comprising a substrate including a through-hole, a display area surrounding the through-hole, and a surrounding area between the through-hole and the display area, a light emitting element disposed in the display area, an insulation film disposed on the substrate, and a disconnection leading structure positioned in the surrounding area and including a void portion in a lower portion thereof.

In the display device according to exemplary embodiments of the disclosure, the disconnection leading structure may include a first metal layer disposed on the insulation film, the void portion disposed on the first metal layer, a third metal layer disposed on the void portion, and an organic film covering the first metal layer, the void portion, and the third metal layer.

In the display device according to exemplary embodiments of the disclosure, the organic film may include a first organic film and a second organic film disconnected by a groove. The first organic film and the second organic film may have a forward tapered shape.

In the display device according to exemplary embodiments of the disclosure, the third metal layer may include a 3a-th metal layer disposed on a side of the first organic film and a 3b-th metal layer disposed on a side of the second organic film.

In the display device according to exemplary embodiments of the disclosure, the 3a-th metal layer and the 3b-th metal layer may have the same width.

In the display device according to exemplary embodiments of the disclosure, the 3a-th metal layer and the 3b-th metal layer may have different widths.

In the display device according to exemplary embodiments of the disclosure, the void portion may include a first void portion disposed on a side of the first organic film and a second void portion disposed on a side of the second organic film.

In the display device according to exemplary embodiments of the disclosure, the first void portion and the second void portion may have the same width.

In the display device according to exemplary embodiments of the disclosure, the first void portion and the second void portion may have different widths.

The display device according to exemplary embodiments of the disclosure may further comprise a second metal layer pattern disposed between the void portion and the organic film.

The display device according to exemplary embodiments of the disclosure may further comprise a light emitting stack pattern disposed on the first metal layer, a second electrode pattern disposed on the light emitting stack pattern, and a first inorganic encapsulation layer pattern disposed on the second electrode pattern. The void portion may be disposed between the organic film and the light emitting stack pattern, the second electrode pattern, and the first inorganic encapsulation layer pattern.

The display device according to exemplary embodiments of the disclosure may further comprise a transistor positioned on the substrate and including a semiconductor layer, a gate electrode overlapping the semiconductor layer, and a source electrode and a drain electrode electrically connected to the semiconductor layer.

In the display device according to exemplary embodiments of the disclosure, the source electrode and the drain electrode may include a first electrode layer, a second electrode layer, and a third electrode layer sequentially stacked. The first metal layer and the first electrode layer may include the same material. The third metal layer and the third electrode layer may include the same material. The void portion may include the same height as a thickness of the second electrode layer.

The display device according to exemplary embodiments of the disclosure may further comprise a planarization layer disposed on the transistor, and a connecting electrode positioned on the planarization layer and electrically connecting the light emitting element and the transistor.

In the display device according to exemplary embodiments of the disclosure, the connecting electrode may include a first connecting electrode layer, a second connecting electrode layer, and a third connecting electrode layer sequentially stacked. The first metal layer and the first connecting electrode layer may include the same material, and the third metal layer and the third connecting electrode layer may include the same material. The void portion may include the same height as a thickness of the second connecting electrode layer.

In the display device according to exemplary embodiments of the disclosure, the disconnection leading structure may have a closed circuit shape to surround the through-hole.

In the display device according to exemplary embodiments of the disclosure, the light emitting element may include a first electrode, a second electrode, and a light emitting stack positioned between the first electrode and the second electrode. The light emitting stack may extend to the surrounding area, and be disconnected by the disconnection leading structure.

In the display device according to exemplary embodiments of the disclosure, the second electrode may be disposed on the light emitting stack and be disconnected by the disconnection leading structure.

The display device according to exemplary embodiments of the disclosure may further comprise a metal pattern positioned in the surrounding area and recessed inward on the insulation film. The light emitting stack may be disconnected by the metal pattern.

The display device according to exemplary embodiments of the disclosure may further comprise a dam in the surrounding area. The disconnection leading structure may be disposed in at least one of an area between the dam and the display area or an area between the dam and the through-hole.

The display device according to exemplary embodiments of the disclosure may further comprise an encapsulation layer disposed on the light emitting element. The encapsulation layer may further include a first inorganic encapsulation layer disposed to extend to the surrounding area, an organic encapsulation layer positioned on the first inorganic encapsulation layer and disposed adjacent to the dam, and a second inorganic encapsulation layer positioned on the organic encapsulation layer and extending to the surrounding area to be disposed to contact the first inorganic encapsulation layer.

According to exemplary embodiments of the disclosure, there may be provided a display device comprising a substrate including a through-hole, a display area surrounding the through-hole, and a surrounding area between the through-hole and the display area, a light emitting element disposed in the display area, an insulation film disposed on the substrate, an organic film positioned in the surrounding area and including an undercut area recessed inward in a lower portion thereof, a first metal layer positioned in the undercut area and disposed on the insulation film, a third metal layer overlapping the first metal layer and disposed on an upper surface of the undercut area, and a void portion disposed between the first metal layer and the third metal layer.

In the display device according to exemplary embodiments of the disclosure, the light emitting element may include a first electrode, a second electrode, and a light emitting stack positioned between the first electrode and the second electrode. The light emitting stack may extend to the surrounding area, and be disconnected by the void portion.

In the display device according to exemplary embodiments of the disclosure, the second electrode may be disposed on the light emitting stack and be disconnected by the void portion.

The display device according to exemplary embodiments of the disclosure may further comprise a metal pattern positioned in the surrounding area and recessed inward on the insulation film. The light emitting stack may be disconnected by the metal pattern.

In the display device according to exemplary embodiments of the disclosure, the organic film may have a closed circuit shape to surround the through-hole.

The display device according to exemplary embodiments of the disclosure may further comprise a second metal layer pattern between the void portion and the organic film.

According to exemplary embodiments of the disclosure, there may be provided a display device comprising a substrate including a through-hole, a display area surrounding the through-hole, and a surrounding area between the through-hole and the display area, a light emitting element disposed in the display area, an insulation film disposed on the substrate; an organic film positioned in the surrounding area and including an undercut area recessed inward in a lower portion thereof, and a void portion disposed on an upper surface of the undercut area.

The display device according to exemplary embodiments of the disclosure may further comprise a first metal layer and third metal layer. The first metal layer may be positioned in the undercut area, and be disposed on the insulation film. The third metal layer may overlap the first metal layer, and be disposed on the upper surface of the undercut area. The void portion may be disposed between the first metal layer and the third metal layer.

In the display device according to exemplary embodiments of the disclosure, the light emitting element may include a first electrode, a second electrode, and a light emitting stack positioned between the first electrode and the second electrode. The light emitting stack may extend to the surrounding area, and be disconnected by the void portion.

In the display device according to exemplary embodiments of the disclosure, the second electrode may be disposed on the light emitting stack and be disconnected by the void

The display device according to exemplary embodiments of the disclosure may further comprise a metal pattern positioned in the surrounding area and recessed inward on the insulation film. The light emitting stack may be disconnected by the metal pattern.

In the display device according to exemplary embodiments of the disclosure, the organic film may have a closed circuit shape to surround the through-hole.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed is:

1. A display device, comprising:
a substrate including a through-hole, a display area surrounding the through-hole, and a surrounding area between the through-hole and the display area;
a light emitting element in the display area;
an insulation film on the substrate; and
a disconnection leading structure in the surrounding area, the disconnection leading structure including a void portion in a lower portion of the disconnection leading structure.

2. The display device of claim 1, wherein the disconnection leading structure includes:
a first metal layer on the insulation film;
the void portion on the first metal layer;
a third metal layer on the void portion; and
an organic film that covers the first metal layer, the void portion, and the third metal layer.

3. The display device of claim 2, wherein the organic film includes a first organic film and a second organic film, the first organic film and the second organic film disconnected from each other by a groove, and
wherein the first organic film and the second organic film have a forward tapered shape.

4. The display device of claim 3, wherein the third metal layer includes a 3a-th metal layer on a side of the first organic film and a 3b-th metal layer on a side of the second organic film.

5. The display device of claim 3, wherein the void portion includes a first void portion on a side of the first organic film and a second void portion on a side of the second organic film.

6. The display device of claim 2, further comprising:
a light emitting stack pattern on the first metal layer;
a second electrode pattern on the light emitting stack pattern; and
a first inorganic encapsulation layer pattern on the second electrode pattern,
wherein the void portion is between the organic film and the light emitting stack pattern, the second electrode pattern, and the first inorganic encapsulation layer pattern.

7. The display device of claim 2, further comprising:
a transistor on the substrate, the transistor including a semiconductor layer, a gate electrode overlapping the semiconductor layer, and a source electrode and a drain electrode electrically connected to the semiconductor layer.

8. The display device of claim 7, wherein the source electrode and the drain electrode include a first electrode layer, a second electrode layer, and a third electrode layer sequentially stacked,
wherein the first metal layer and the first electrode layer include a same material,
wherein the third metal layer and the third electrode layer include a same material, and
wherein the void portion includes a same height as a thickness of the second electrode layer.

9. The display device of claim 7, further comprising:
a planarization layer on the transistor; and
a connecting electrode on the planarization layer, the connecting electrode electrically connecting the light emitting element and the transistor.

10. The display device of claim 9, wherein the connecting electrode includes a first connecting electrode layer, a second connecting electrode layer, and a third connecting electrode layer, the first connecting electrode layer, the second connecting electrode layer, and the third connecting electrode layer sequentially stacked,
wherein the first metal layer and the first connecting electrode layer include a same material,
wherein the third metal layer and the third connecting electrode layer include a same material, and
wherein the void portion includes a same height as a thickness of the second connecting electrode layer.

11. The display device of claim 1, wherein the disconnection leading structure has a closed circuit shape that surrounds the through-hole.

12. The display device of claim 1, wherein the light emitting element includes a first electrode, a second electrode, and a light emitting stack between the first electrode and the second electrode, and
wherein the light emitting stack extends to the surrounding area, and is disconnected by the disconnection leading structure.

13. The display device of claim 12, wherein the second electrode is on the light emitting stack and is disconnected by the disconnection leading structure.

14. The display device of claim 12, further comprising:
a metal pattern in the surrounding area, the metal pattern recessed inward on the insulation film,
wherein the light emitting stack is disconnected by the metal pattern.

15. The display device of claim 1, further comprising:
a dam in the surrounding area,
wherein the disconnection leading structure is in at least one of an area between the dam and the display area or an area between the dam and the through-hole.

16. A display device, comprising:
a substrate including a through-hole, a display area surrounding the through-hole, and a surrounding area between the through-hole and the display area;
a light emitting element in the display area;
an insulation film on the substrate;
an organic film in the surrounding area, the organic film including an undercut area recessed inward in a lower portion thereof; and
a void portion disposed on an upper surface of the undercut area.

17. The display device of claim 16, wherein further comprising a first metal layer and third metal layer,
wherein the first metal layer is positioned in the undercut area, and is disposed on the insulation film,
wherein the third metal layer overlaps the first metal layer, and is disposed on the upper surface of the undercut area, and
wherein the void portion is disposed between the first metal layer and the third metal layer.

18. The display device of claim 16, wherein the light emitting element includes a first electrode, a second electrode, and a light emitting stack positioned between the first electrode and the second electrode, and
wherein the light emitting stack extends to the surrounding area, and is disconnected by the void portion.

19. The display device of claim 18, wherein the second electrode is on the light emitting stack and is disconnected by the void portion.

20. The display device of claim 16, wherein the organic film has a closed circuit shape that surrounds the through-hole.
